(19) United States
(12) Patent Application Publication
(10) Pub. No.: US 2019/0081559 A1
(43) Pub. Date: Mar. 14, 2019

(54) Energy Harvesting Systems and Methods

(71) Applicant: Cambridge Enterprise Limited, Cambridge Cambridgeshire (GB)

(72) Inventors: Ashwin Seshia, Cambridge, Cambridgeshire (GB); Sijun Du, Cambridge, Cambridgeshire (GB); Yu Jia, Cambridge, Cambridgeshire (GB)

(21) Appl. No.: 16/080,370

(22) PCT Filed: Feb. 28, 2017
(86) PCT No.: PCT/GB2017/050534

§ 371 Date: Aug. 28, 2018

(30) Foreign Application Priority Data
Feb. 29, 2016 (GB) 1603475.3

(51) Int. Cl. H02M 3/07; H02N 2/18; H02M 7/219

(52) U.S. Cl. CPC H02M 3/07; H02N 2/181; G01R 19/175; H02N 2/186; H02M 2007/2195; H02M 7/219

(57) ABSTRACT

A method of energy harvesting from an electromechanical device providing alternating current (AC) electrical power via a rectifier. The method comprises: identifying when a current flow from the device is substantially zero and, responsive to this identifying: connecting and disconnecting a first charge storage capacitor in parallel with the device with a first sense, such that charge on the device is shared with the first charge storage capacitor, to collect charge from the device on the first charge storage capacitor; preferably clearing the remaining charge on the electromechanical device; and then connecting and disconnecting the first charge storage capacitor in parallel with the device in a second, opposite sense to the first sense, such that the collected charge on the first charge storage capacitor is shared with opposite polarity with the device, to replace opposite polarity charge from the first charge storage capacitor onto the device.

### FIELD OF THE INVENTION

This invention relates to methods, circuits and systems for harvesting energy from an electromechanical device, in embodiments a piezoelectric device.

### BACKGROUND TO THE INVENTION

Vibration-based energy harvesters are used to extract energy from mechanical vibrations in order to power local devices or in order to store that energy for later use. Piezoelectric materials are widely used in vibration-based energy harvesters, which are also called piezoelectric vibration-based energy harvesters. Between the harvesters and the energy storage, a power-conditioning interface circuit is employed to transfer the energy generated by the harvesters into the energy storage. In order to improve the overall energy efficiency of the vibration-based energy harvesting system, power-conditioning interface circuit design is very important.

General background prior art can be found in: US2010/0079034; US2014/0021828; US2011/0227543; EP2395625A; EP2469693A; US2007/0029883; U.S. Pat. No. 6,087,863; and WO2010/146090.

While a piezoelectric vibration-based energy harvester vibrates, it can be approximately modelled as a current source, I_{P}, in parallel with an internal capacitor, C_{P}, which is formed by the electrode pair(s) of the harvester.

Full-bridge rectifiers are widely used to rectify the AC signal from the harvester and store the energy in a reservoir capacitor, as shown in FIG. 1a. In order to transfer energy from the harvester to the reservoir capacitor, the absolute value of the voltage in the harvester should be greater than a threshold set by the voltage of the storage capacitor and the forward voltage drop of the diodes used in the full-bridge rectifier. Defining the reservoir capacitor as C_{S}, the voltage of C_{S} as V_{S}, the forward voltage drop of the diodes as V_{D} and the voltage from the piezoelectric vibration-based energy harvester as V_{piezo} (V_{piezo}=V_{P}−V_{N}), the condition for the energy to be transferred to the reservoir capacitor is V_{piezo}>V_{S}+2V_{D} or V_{piezo}<−(V_{S}+2V_{D}). If the environmental vibrational excitation input is so small that neither of the above conditions is satisfied, all of the generated energy by the harvester is wasted in the full-bridge rectifier. If the vibrational excitation input is great enough to meet the conditions, the internal capacitor of the harvester C_{P} needs to be discharged so that its voltage V_{piezo} goes from ±(V_{S}+2V_{D}) to ∓(V_{S}+2V_{D}) for each half cycle of the vibration excitation input, in order to transfer energy to the reservoir capacitor in the following half vibration cycle. As a result, the energy used for charging C_{P} is wasted and the amount of wasted charge per a half excitation period is 2C_{P}(V_{S}+2V_{D}), as shown in the black area in FIG. 1a.

FIG. 1b shows an example of a Synchronized Switch Harvesting on Inductor (SSHI) power-conditioning interface circuit, presently one of the most power-efficient interface circuits for piezoelectric vibration energy harvesters. This employs an inductor in parallel with the electromechanical device (harvester) to form a RLC (resistor-inductor-capacitor) close loop in order to invert the voltage V_{piezo} from ±(V_{S}+2V_{D}) towards ∓(V_{S}+2V_{D}). The inductor is controlled by one or two synchronized switches, φ_{SSHI}, to perform the charge inversion at times when the voltage V_{piezo} changes from ±(V_{S}+2V_{D}) to ∓(V_{S}+2V_{D}). While inverting V_{piezo}, there is always some charge loss due to the resistance of the switches, so that the resulting voltage cannot attain ∓(V_{S}+2V_{D}). The loss is shown as Vₜₕ in the waveform of the figure.

The inventors have, however, recognized that there are some significant hidden drawbacks of the SSHI interface circuit. One drawback arises because the switches have a finite, if low, on-resistance. This makes the circuit inefficient with lower inductance vales, and a large inductor is preferable to reduce the charging loss in the RLC loop and achieve efficient inversion of the polarization of the voltage on the harvester. This is particularly the case parasitic resistance is taken into account. However a large inductor is physically large, relatively costly, and unsuited to integration with miniaturized systems. In addition in a real-world implementation the pulse width for the switching needs to be precisely tuned to half of the pseudo-period of the RLC oscillation network. This adds complexity and instability of the energy harvesting system.

There is therefore a need for improved approaches which address the above deficiencies, and which in particular facilitate fabrication of a low-volume circuit or integrated circuit as well as providing efficient operation.

### SUMMARY OF THE INVENTION

According to the present invention there is therefore provided a method of energy harvesting from an electromechanical device which provides energy in the form of charge separation, the method comprising: providing alternating current (AC) electrical power from said electromechanical device to an energy storage device via a rectifier to convert positive and negative components of said AC power to power having a single polarity for storage on said storage device: the method further comprising: identifying when a current flow from said electromechanical device is substantially zero and, responsive to said identifying: connecting and disconnecting a first charge storage capacitor in parallel with said electromechanical device with a first sense, such that charge on said electromechanical device is shared with said first charge storage capacitor, to collect charge from said electromechanical device on said first charge storage capacitor; and then connecting and disconnecting said first charge storage capacitor in parallel with said electromechanical device in a second, opposite sense to said first sense, such that said collected charge on said first charge storage capacitor is shared with opposite polarity with said electromechanical device, to replace opposite polarity charge from said first charge storage capacitor onto said electromechanical device.

In broad terms, embodiments of the method use one or more charge storage capacitors to store charge from the electromechanical device and replace it back on to the device at a zero crossing of the current supplied by the electromechanical device. This reduces a time for which power transfer is effectively lost as a consequence of the conduction threshold voltage of one or more diodes of the rectifier. The rectifier is typically a full-bridge rectifier between the electromechanical device and an ultimate storage device such as a reservoir capacitor or battery.

Furthermore, because the circuit employs capacitors rather than inductors it is easier to fabricate and more compact. In principle an energy harvesting circuit implementing the method may be fabricated on a single CMOS integrated circuit, optionally in combination with a MEMS (Micro Electrical Mechanical System) energy harvester. The electromechanical device has an internal capacitance, and it is charge on this internal capacitance which is shared with the charge storage capacitor. Typically the electromechanical device comprises a piezoelectric material and in some preferred embodiments is a MEMS device.

In preferred implementations of the method the electromechanical device is shorted (briefly) between collecting charge from the device and replacing charge onto the device. However this is not essential, particularly where multiple charge storage capacitors are employed.

In principle various circuit configurations may be employed for connecting and disconnecting the charge storage capacitor but in preferred embodiments controllable switches are employed, for example MOS (CMOS) switches. As the skilled person will appreciate, various switch configurations may be employed—for example to connect each end of the charge storage capacitor to the energy harvester with a reversible polarity four ON/OFF switches or two changeover switches may be employed. The charge sharing is virtually instantaneous apart from stray inductance, and internal resistance of the switches, and it is therefore preferable to employ low resistance switches for fast operation. In preferred embodiments the switches are controlled by one or more pulse generators which generate one or more sequences of pulses, in particular to control the switches in synchronism with detected zero crossings of the AC current from the energy harvester. As the skilled person will be aware such a zero crossing may be detected in many ways including by voltage sensing (to detect when the voltage from the energy harvester is approximately the same as the voltage drop across the diodes/rectifier), and by current sensing (using a current sense resistor connected in series with the power to or from the energy harvester).

The electromechanical device may be modelled as including a capacitor, and when charge is shared between this capacitor and the charge storage capacitor the voltage on these two capacitors substantially equalizes. One might imagine that after charge sharing the voltages on these capacitors would be half that immediately before a zero-crossing moment. In this case when charge is shared again to replace charge onto the energy harvester the voltage boost provided to the energy harvester would be a quarter of this initial voltage. However the effect of accumulating residual charge on the charge storage capacitor, as described later, results in the shared voltage being two thirds of that immediately before a zero crossing, so that a boost of one third this voltage is applied when the charge is replaced. (The mathematics behind this is set out later).

Preferably but not essentially the value of the charge storage capacitor should be of a similar magnitude to the internal capacitance of the energy harvester, more preferably approximately equal to this internal capacitance. Where multiple charge storage capacitors are employed (see below) this preferably applies to each of them.

The voltage boost applied to the internal capacitance of the energy harvester can be increased by employing multiple charge storage capacitors. In broad terms, charge is shared with a first of these and then residual charge on the internal capacitance of the energy harvester is shared with a second of these, and so forth, each charge sharing capturing a further fraction of the residual charge. In principle employing a large number of charge storage capacitors should be able to capture substantially all the charge from the energy harvester, but in practice there are diminishing returns and close to optimum performance can be achieved with a relatively low number of charge storage capacitors. Thus in embodiments there are more than two, three or four charge storage capacitors but less than for example 12, 16, 24 or 32 charge storage capacitors—for example there may be four to eight charge storage capacitors.

When multiple charge storage capacitors are employed they are preferably connected sequentially to the energy harvester to capture charge from the energy harvester (where the connecting involves connecting and then disconnecting a capacitor to capture shared charge). They are then reconnected in the reverse order, preferably after shorting out the energy harvester to zero residual charge on its internal capacitance. It will be appreciated, however, that shorting the energy harvester is not essential, particularly where almost all of the charge is removed from the energy harvester.

In a related aspect the invention provides a circuit for energy harvesting from an electromechanical device which provides energy in the form of charge separation, the circuit comprising: an input to receive alternating current (AC) electrical power from said electromechanical device; a rectifier to convert positive and negative components of said AC power to power having a single polarity for storage on an energy storage device; a zero-crossing circuit to identify when a current flow from said electromechanical device is substantially zero; a first charge storage capacitor; a first plurality of switches configured to connect and disconnect said first charge storage capacitor in parallel with said electromechanical device in a first sense and in a second opposite sense; at least one shorting switch to short said electromechanical device to reduce or zero a charge on said electromechanical device; and a controller, coupled to said zero-crossing circuit to control said first plurality of switches and said at least one shortening switch to: connect and disconnect said first charge storage capacitor in parallel with said electromechanical device in said first sense to collect charge from said electromechanical device; then short said electromechanical device reduce or zero a charge on said electromechanical device; and then connect and disconnect said first charge storage capacitor in parallel with said electromechanical device in said opposite sense to return said collected charge to said electromechanical device with an opposite polarity.

The invention further provides an energy harvesting circuit to harvest energy from a piezoelectric device, the circuit comprising: an input comprising first and second connections to receive ac power from said piezoelectric device; and a rectification stage, coupled to said input; the circuit further comprising: a first controllable multi-state switching system; and a first charge storage capacitor coupled to said input connections by said first controllable multi-state switching system; wherein said controllable multi-state switching system comprises two or more controllable switches configured such that when said switching system is in a storage state first and second plates of said first charge storage capacitor are respectively coupled to said first and second input connections; such that when said switching system is in a recovery state first and second plates of said first charge storage capacitor are respectively coupled to said second and first input connections; and such that when said switching system is in a quiescent state at least one of said plates of said first charge storage capacitor is decoupled from said input connections; and a clock generator, synchronised to said ac power from said piezoelectric device, to control said switching system to switch from said quiescent state and transition between said storage and recovery states at a zero crossing of an AC current from said piezoelectric device.

Preferably the switching system has a transitional state in which the input connections are connected together (shorted) and includes a switch for this purpose. The clock generator may then control the switching system into this transitional state between the storage and recovery states.

Embodiments may further comprise a second charge storage capacitor coupled to the input connections by a second controllable multi-state switching system. The clock generator may then control the first and second switching systems to successively switch said first and then the second switching system between its quiescent state and a respective storage state and then back to the quiescent state; and then to successively switch the second then the first switching system between its quiescent state and a respective recovery state and then back to the quiescent state. Again preferably the clock generator is configured to control the switching system into the transitional state between the sequence of storage state switchings and the sequence of recovery state switchings.

As the skilled person will appreciate the above described methods and circuits may be implemented in discrete components or partially or wholly in an integrated circuit.

### BRIEF DESCRIPTION OF THE DRAWINGS

These and other aspects of the invention will now be further described, by way of example only, with reference to the accompanying figures in which:

FIGS. 1a and 1b show, respectively, an energy harvester power conditioning circuit comprising a bridge rectifier and a Synchronized Switch Harvesting on Inductor (SSHI) energy harvester power conditioning circuit;

FIG. 2 shows a circuit diagram of an energy harvesting power conditioning circuit according to a first embodiment of the invention;

FIG. 3 shows a circuit diagram of an energy harvesting power conditioning circuit according to a further embodiment of the invention;

FIGS. 4a to 4c show simulation waveforms for the circuit of FIG. 2;

FIGS. 5a and 5b show simulation waveforms for a version of the circuit of FIG. 3;

FIGS. 6a and 6b show, respectively, a more detailed example of a power conditioning circuit according to an embodiment of the invention, and a block diagram of a power conditioning system including the power conditioning circuit of FIG. 6a;

FIG. 7 illustrates the operation of the circuit of FIG. 6a;

FIG. 8 shows theoretical output electrical power from a power conditioning circuit according to an embodiment of the invention;

FIGS. 9a to 9c show experimentally measured waveforms corresponding to the simulated waveforms of FIGS. 4a to 4c;

FIG. 10 shows the system architecture of a further example implementation;

FIGS. 11a and 11b show a zero-crossing detector block for the implementation of FIG. 10 showing, respectively, a circuit diagram of the block and associated waveforms;

FIG. 12 shows a pulse generation block for the implementation of FIG. 10;

FIG. 13 shows a pulse sequencing block for the implementation of FIG. 10;

FIG. 14 shows waveforms of the pulse sequencing block of FIG. 13;

FIG. 15 shows a switch control block for the implementation of FIG. 10;

FIG. 16 shows a circuit diagram of a voltage regulator and over-voltage protection for the implementation of FIG. 10;

FIGS. 17a to 17d show measured waveforms and switch signals (some ORed for ease of representation) for circuits with 1, 2, 4 and 8 switched capacitors respectively; and

FIG. 18 shows measured electrical output power from a piezoelectric transducer comparing a full-bridge rectifier (FBR) circuit with circuits according to embodiments of the invention, showing (a) output power over a range of V_{S} with a fixed V_{OC}=2.5V (equivalent to an acceleration level 1.2 g) and (b) output power measured over a wide range of excitation levels up to V_{OC}=15V (equivalent to 7.5 g) with a fixed V_{S}=5V.

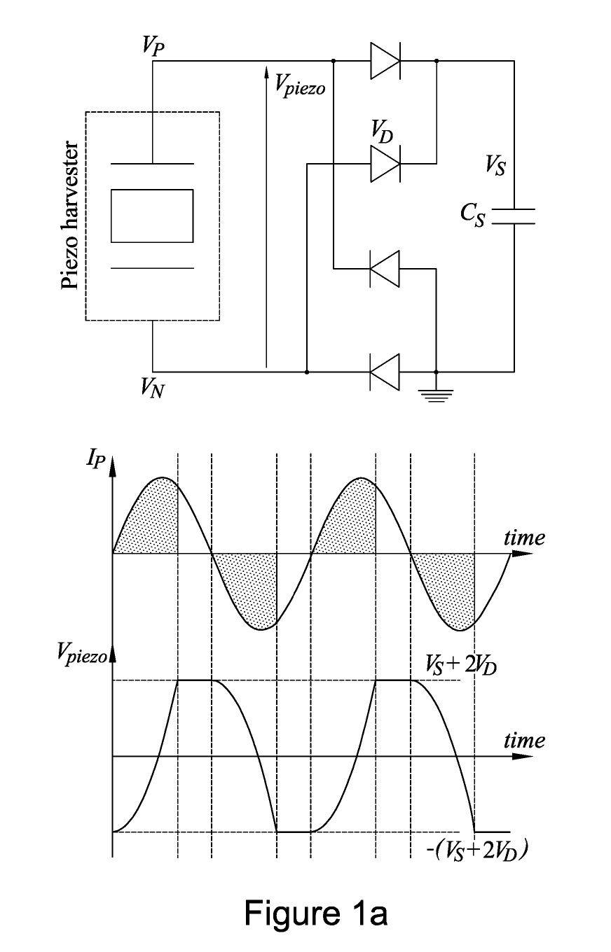

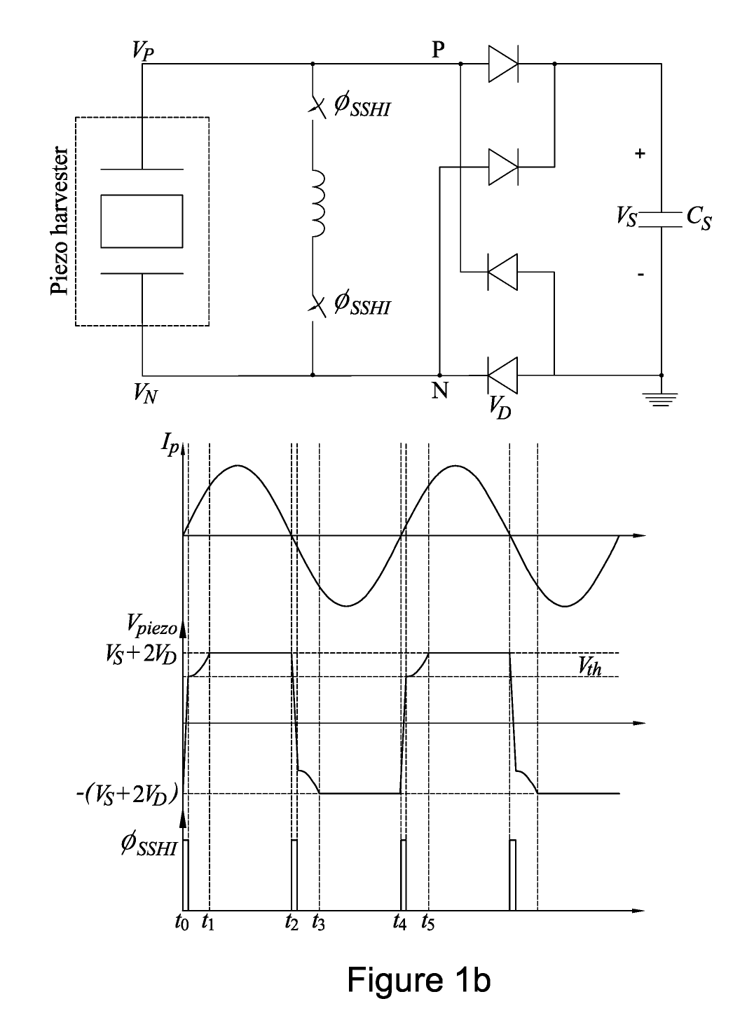

### DETAILED DESCRIPTION OF PREFERRED EMBODIMENTS

Broadly speaking we will describe efficient power-conditioning interface circuits for vibration-based energy harvesters, which significantly improve energy efficiency by synchronously inverting the voltage of the energy harvester using switched capacitors. Thus we describe our approach as Harvesting on Synchronised Switched Capacitors (HSSC).

In embodiments we synchronously flip the voltage across the piezoelectic transducer (PT) using one or multiple switched capacitors instead of an inductor. Our approach does not require any inductor and thus significantly reduces the required system volume. This feature is especially useful for miniaturized energy harvesting systems, such as implantable devices and miniaturized wireless sensor nodes. The circuits we describe can also achieve high voltage flip efficiency, and improved higher energy extraction efficiency

Thus embodiments of the techniques we describe perform charge inversion to invert the voltage V_{piezo} from ±(V_{S}+2V_{D}) towards ∓(V_{S}+2V_{D}) using one or more switched capacitor(s) instead of an inductor, and in this way the volume and cost of the system can be significantly decreased.

When using one switched capacitor, V_{piezo} can be set to ∓⅓(V_{S}+2V_{D}) from ±(V_{S}+2V_{D}). A circuit with two, three or more switched capacitors may also be used: The larger the number of switched capacitors used, the greater the charge which can be inverted to thus move V_{piezo} closer to ∓(V_{S}+2V_{D}) after inversion.

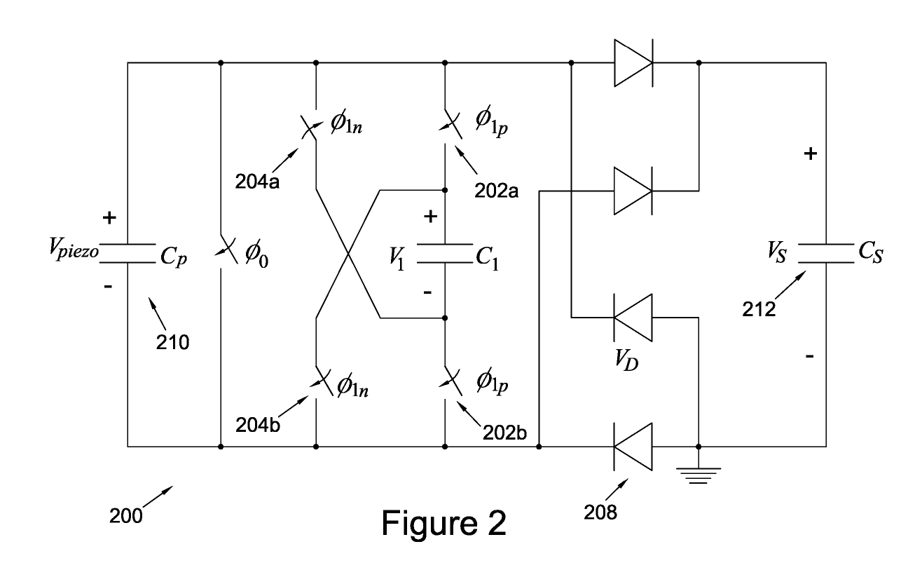

Referring to FIG. 2, this shows a circuit diagram of an energy harvester power conditioning circuit 200 according to an embodiment of the invention. The embodiment of FIG. 2 employs one switched charge-storage capacitor, C₁. The energy harvester 210 may be modelled as a current source (not shown in the figure) driven by a mechanical excitation (vibration), in parallel with a device capacitance C_{P}. The illustrated circuit includes a first pair of switches 202a,b able to connect C₁ to V_{piezo} with a first polarity and a second pair of switches 204a,b able to connect C₁ to V_{piezo} with a second, opposite polarity. A third switch 206 is configured to short V_{piezo}. In the following description the switches are sometimes referred to interchangeably with the signal phases which drive them, so that switches 202a,b may be referred to as switches Ø₁ₚ switches 204a,b may be referred to as switches Ø₁ₙ, and switch 206 may be referred to as switch Ø₀. Other switch configurations are possible—for example switches 202a,b and 204a,b could be replaced by a pair of changeover switches. The AC power from energy harvester 210 is rectified by a set of diodes 208, in the illustrated example a full bridge, and preferably provided a reservoir 212 such as a battery or further, reservoir capacitor.

In FIG. 2 three signals, in embodiments pulses, are used to control the switches shown to perform the charge inversion, in the nomenclature of FIG. 2 having respective phases (periods when active), Ø₁ₚ, Ø₀ and Ø₁ₙ. At the times when V_{piezo} inverts a pulse generator (not shown) generates these three pulsed signals are sequentially to pulse ON the five switches 202a,b, 206, and 204a,b respectively. Although we refer to inversion of V_{piezo} as will be seen from the waveforms explained later, the sequence of pulses inverting the voltage is preferably (though not essentially) triggered when the current from the energy harvester falls to zero (that is when the diodes of rectifier 208 stop conducting).

When pulse Øhd 1p is active capacitor C₁ is connected to the piezoelectric energy harvester in a first, say positive, sense and the charge stored in the internal capacitor C_{P} (C_{piezo}) of the harvester is distributed between the two capacitors C₁ and C_{P}, in embodiments substantially equally (where C₁≈C_{P}). After this, when pulse Ø₀ is active the remaining charge in internal capacitor C_{P} is cleared by shorting the capacitor. When pulse Ø₁ₚ is active capacitor C₁ is connected to C_{P} in a first, negative, sense. Due to charge conservation the voltage V_{piezo} goes to a negative value and the energy harvester charge is partially inverted.

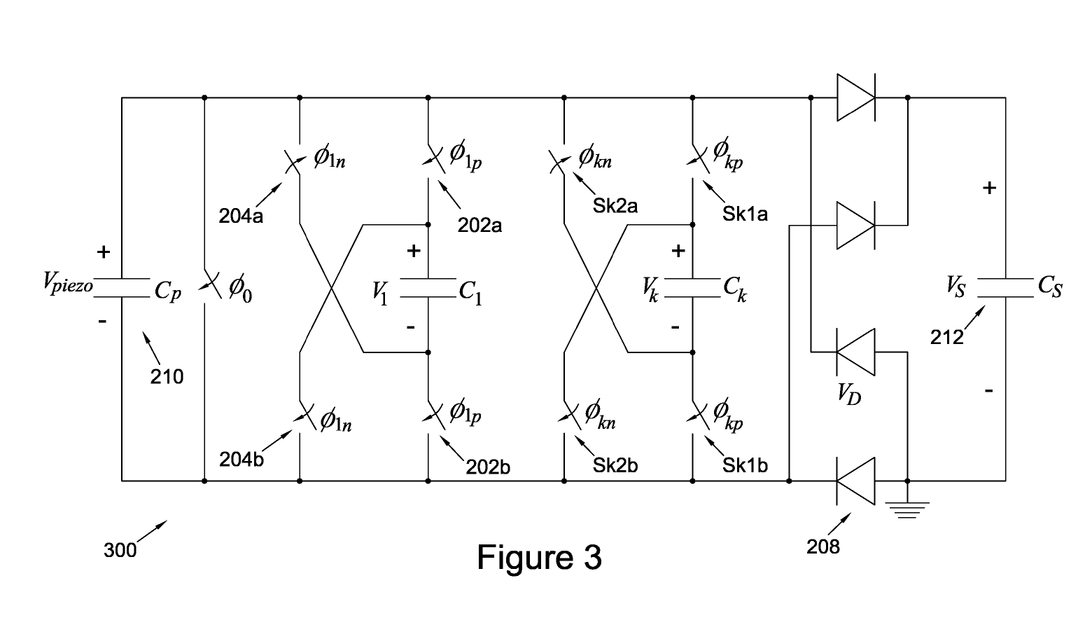

Referring to FIG. 3, this shows a circuit diagram of an energy harvesting power conditioning circuit 300 according to a further embodiment of the invention. The embodiment of FIG. 3 (in which like elements to those of FIG. 2 are indicated by like reference numerals) employs a plurality, k, of switched charge-storage capacitors C₁ . . . Cₖ each with respective switches Sₖ₁a, Sₖ₁b, Sₖ₂a, Sₖ₂b, where k is an integer greater than 1.

When using k switched capacitors, there are in total 2k+1 pulse signals to be generated, denoted Ø₁ₚ, Ø₂ₚ, . . . , Øₖₚ, Ø₀, Øₖₙ, . . . , Ø₂ₙ, Ø₁ₙ; these are generated sequentially in this order. At the time when V_{piezo} inverts the k capacitors are in turn positively connected to the internal capacitor of the harvester C_{P}, that is sequentially in the order of Ø₁ₚ, Ø₂ₚ . . . , Øₖₚ. In this way significantly more charge is stored than in the arrangement of FIG. 2 prior to the charge clearing stage Ø₀. During Ø₀, the residual charge on C_{P} is cleared. In the next stage the k switched capacitors are in turn negatively connected to C_{P}, in reverse order, that is in an inverted sequence with the order of Øₖₙ, . . . , Ø₂ₙ, Ø₁ₙ.

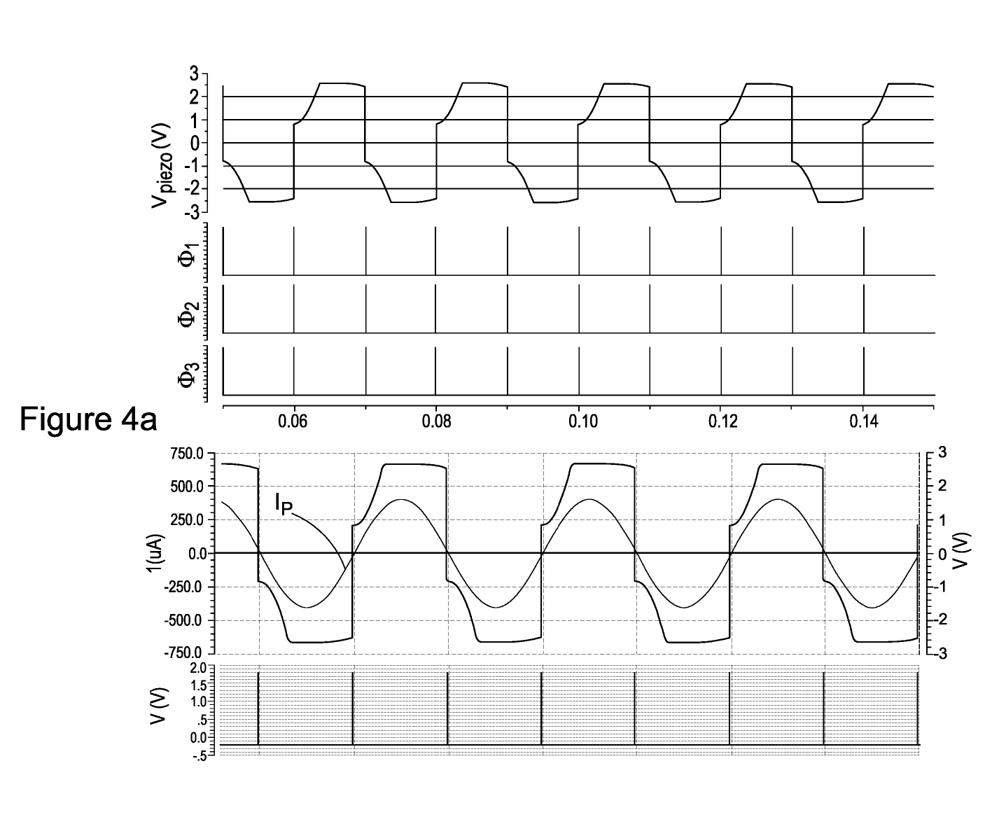

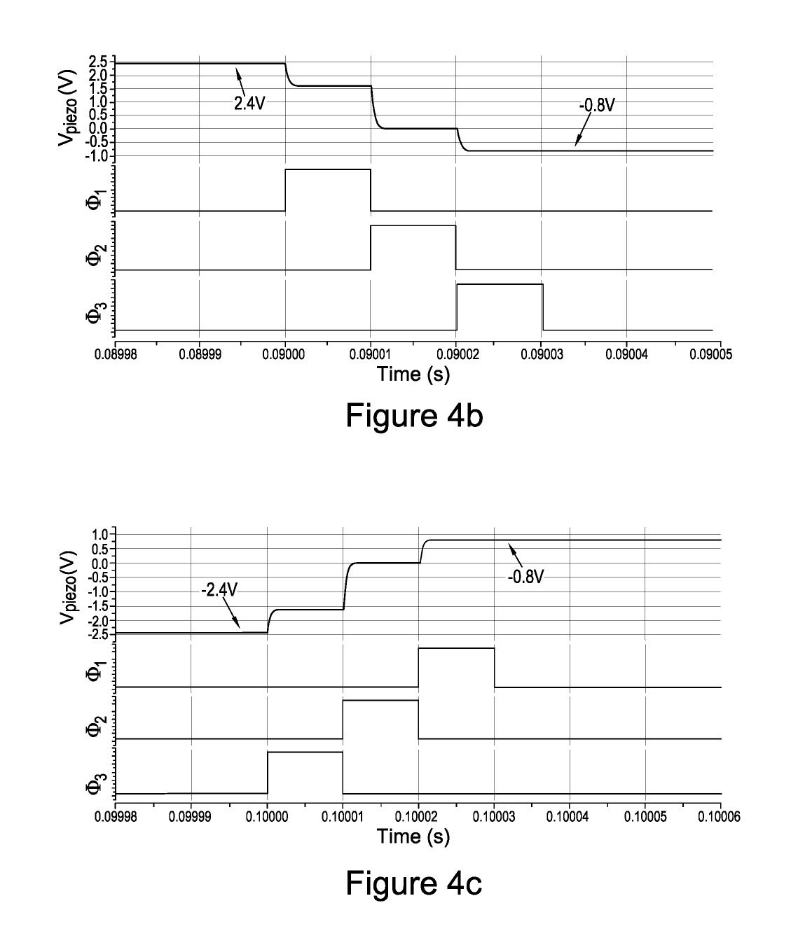

FIG. 4 shows simulation waveforms for the circuit of FIG. 2. The simulation was performed under the following conditions:

I_{P}=I₀ sin 2πft, I₀=400 μA, f=100 Hz, C_{P}=150 nF, C_{S}=0.1 F, V_{D}=0.3 V, V_{S}=2V

FIG. 4a shows the voltage V_{piezo} and three pulse signals φ1, φ2, and φ3 corresponding to Ø₁ₚ, Ø₀ and Ø₁ₙ, all at the timescale of the V_{piezo} waveform, and the inset figure shows the piezo current I_{P}. For each zero-crossing of Iₚ the three pulse signals are generated sequentially and it can be seen that V_{piezo} is partially inverted every half cycle of Iₚ.

FIG. 4b shows in more detail the period when V_{piezo} is inverted from positive to negative, and FIG. 4c the corresponding period when V_{piezo} is inverted from negative to positive.

In FIG. 4b switches φ1 (switches 202a,b) are first turned ON and the capacitors, C_{P} and C_{T} are connected in a first polarization. From the waveform of V_{piezo}, it can be seen that at this point it reduces a little (from 2.4V to around 1.6V i.e. ⅔ of its initial value) because the charge on C_{P} is distributed between the two capacitors.

In the φ2 phase, C_{P} is shorted by switch φ2 (switch 206) and the remaining charge in it is cleared, hence V_{piezo} goes to 0 V.

In the φ3 phase switches φ3 (switches 204a,b) are turned ON, and C_{T} and C_{P} are connected in a polarization opposite to that in phase φ1. At this time some charge on C_{T} flows onto C_{P} until they have the same voltage values across them and V_{piezo} goes to a negative value as a result. In the simulation, V_{piezo} equals to 2.4 V before the zero-crossing moment and it goes to −0.8 V (approximately ⅓ of its initial value) after the inversion process.

FIG. 4c shows the corresponding waveforms when V_{piezo} is inverted from negative to positive. In this case the three pulse signals are generated in the order φ3->φ2->φ1. In each of FIG. 4b and FIG. 4c the three signals should preferably be non-overlapping, to avoid unwanted charge flow.

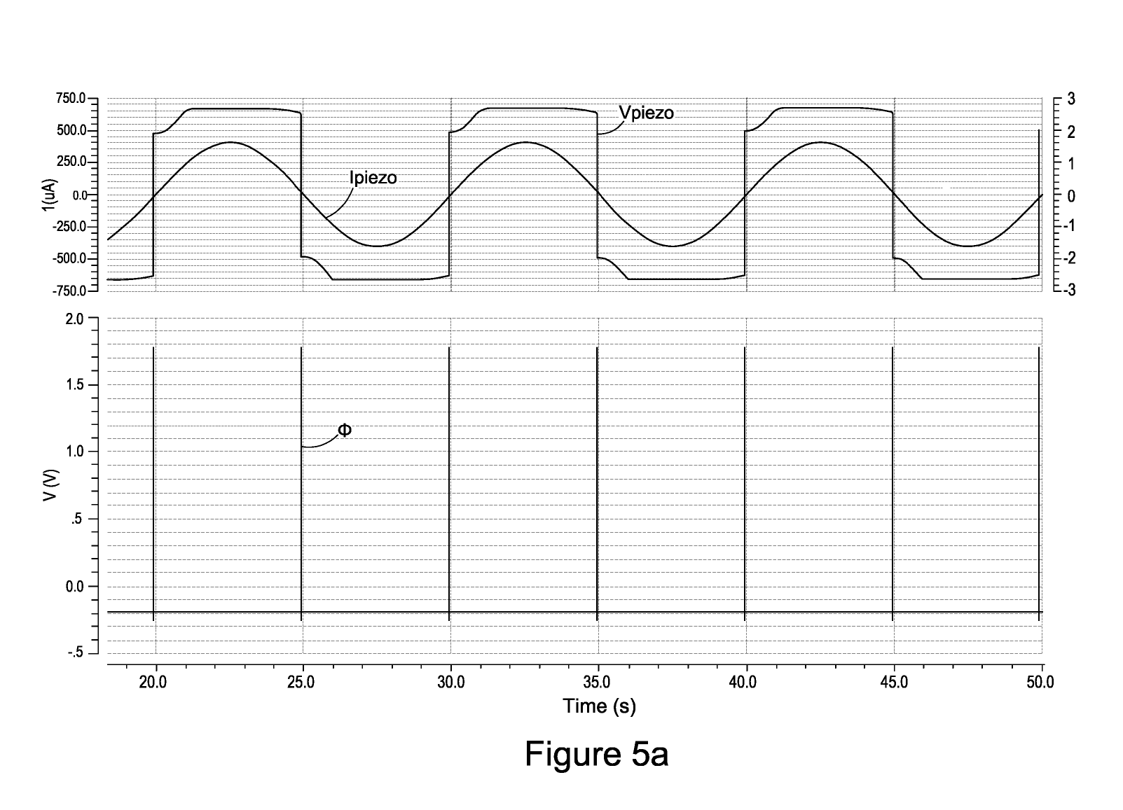

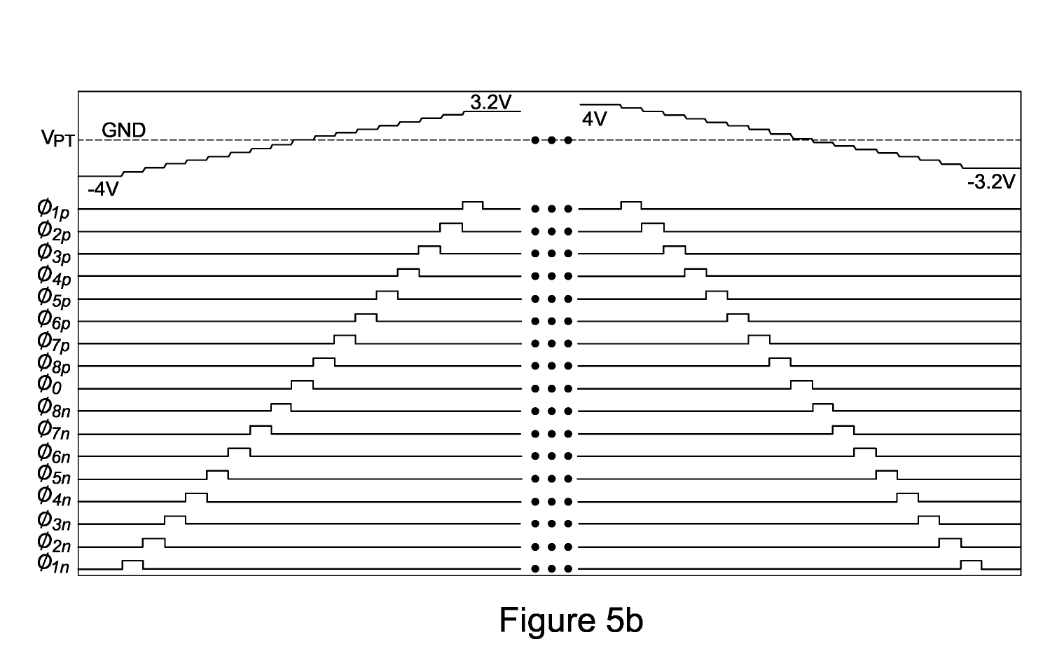

FIG. 5 shows simulation waveforms for an embodiment of the type shown in FIG. 3 using 8 switched capacitors. From FIG. 5a, it can be seen that V_{piezo} is inverted from 2.5 V to 1.98 V (Vₜₕ in the Figure), which implies that almost 80% of the charge is inverted. This demonstrates that a very high energy efficiency can be achieved (efficiencies this high are difficult to achieve with other approaches).

FIG. 5b, which relates to another simulation, shows the 17 pulse signals used for the 8 switched capacitors to invert the voltage V_{piezo}. As shown in FIG. 5b (right hand side), in order to collect and subsequently replace charge for inverting V_{piezo} from V_{S}+2V_{D} towards −(V_{S}+2V_{D}) the order of the pulses is Ø₁ₚ, Ø₂ₚ, Ø₃ₚ, Ø₄ₚ, Ø₅ₚ, Ø₆ₚ, Ø₇ₚ, Ø₈ₚ, Ø₀, Ø₈ₙ, Ø₇ₙ, Ø₆ₙ, Ø₅ₙ, Ø₄ₙ, Ø₃ₙ, Ø₂ₙ, Ø₁ₙ, where the subscripts 1, 2, . . . 8 label the switches associated with the respective charge storage capacitors C₁, C₂, . . . C₈. As shown in FIG. 5b (left hand side), in order to invert V_{piezo} from −(V_{S}+2V_{D}) towards V_{S}+2V_{D}, the order of the pulses is reversed: Ø₁ₙ, Ø₂ₙ, Ø₃ₙ, Ø₄ₙ, Ø₅ₙ, Ø₆ₙ, Ø₇ₙ, Ø₈ₙ, Ø₀, Ø8p, Ø₇ₚ, Ø₆ₚ, Ø₅ₚ, Ø₄ₚ, Ø₃ₚ, Ø₂ₚ, Ø₁ₚ.

In principle the capacitance of each switched capacitor (C₁, C₂ . . . . Cₖ) should preferably be substantially equal to C_{P} in order to achieve optimum charge inversion performance. In practice the value of C_{P} may vary between devices and an approximate match to the particular device used is sufficient.

Preferably pulses Ø₁ₚ, Ø₂ₚ . . . , Øₖₚ, Ø₀, Øₖₙ, . . . , Ø₂ₙ and Ø₁ₙ are non-overlapping for efficiency.

The skilled person will appreciate that this may be generalized to the case of N charge storage capacitors, where there are preferably 2N+1 states (for example 17 states where N=8). The first N states sequentially couple the N capacitors to the input connections of the circuit (the first and second plates of each capacitor are respectively coupled to first and second input connections of the circuit). In the (optional but preferable) neutral state, in order, the middle state in the 2N+1 states, all the storage capacitors are decoupled from the both of the input connections and the two input connections are connected to clear the remaining charge in the piezoelectric device. The final N states sequentially couple the N storage capacitors to the input connections in a reversed order as compared with the first N states (the first and second plates of each capacitor are respectively coupled to the second and first input connections). The first N states may be termed charge storage states and the final N states charge recovery states.

### Example

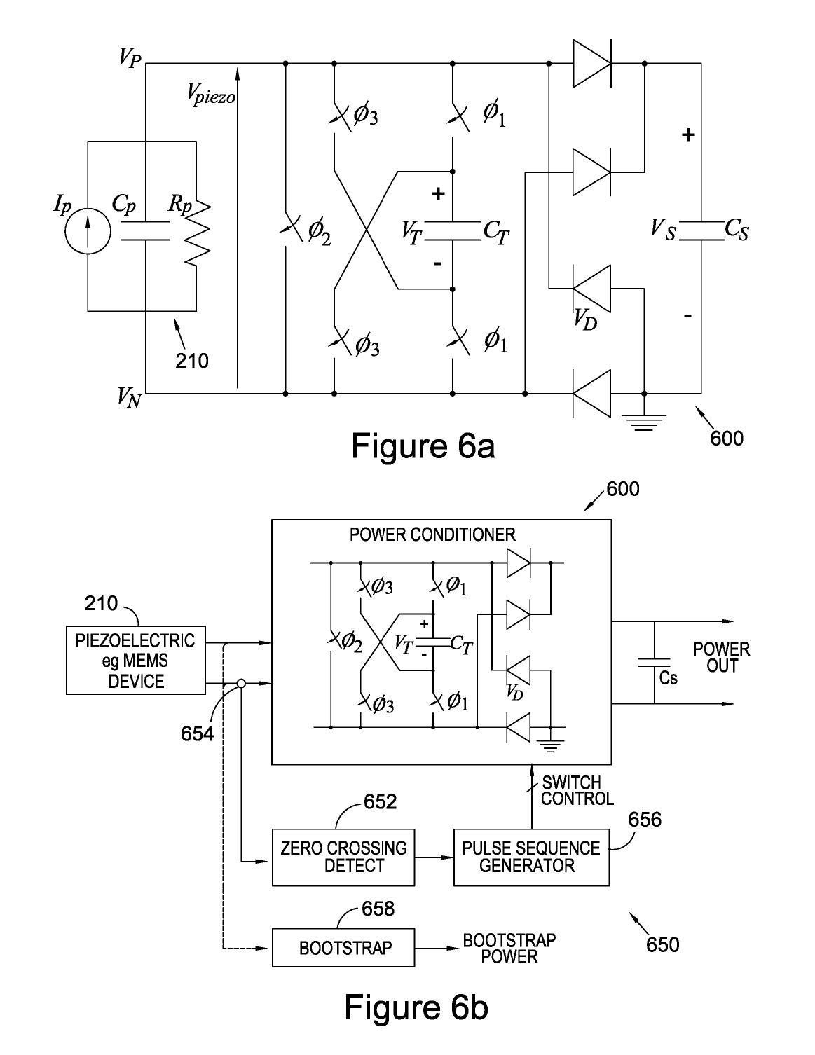

Referring now to FIG. 6a, this shows in slightly more detail an example design of an HSSC (Harvesting on Synchronized Switched Capacitors) power conditioning circuit 600 according to an embodiment of the invention. In FIG. 6a only one capacitor is used to perform the voltage/charge inversion, and a more detailed model of the energy harvester 210 is illustrated. In the example, to perform the charge inversion five analogue switches driven by three pulse signals (φ1, φ2 and φ3) are employed. The three non-overlapping switching signals are synchronously generated to turn ON the five switches sequentially; the order of the three pulses depends on the polarization of the voltage V_{piezo}.

FIG. 6b shows a block diagram of an HSSC system 650 including the circuit 600 of FIG. 6a. The system of FIG. 6b includes a zero-crossing detect circuit 652, coupled to a voltage or current sensor 654, and a pulse generator 656 to generate pulse signals φ1, φ2 and φ3 to control the switches. The system 650 may harvest energy for a device, circuit or system which already has a power supply such as a battery, in which case this may be employed to provide power for the pulse generator. Alternatively an optional bootstrap circuit 658, such as a conventional full bridge driven from the same or a different energy harvester to device 210, may be used to provide power to start up the system 650.

Various zero-crossing detect methods/circuits may be employed, for example detecting the maximum and minimum values of Vpiezo, which are also the zero-crossings of Ip. In one embodiment the zero-crossing detect circuit 652 operates as follows: when I_{P} is close to zero, the diodes of the full-bridge rectifier are just about to turn OFF. At this instant, one of V_{P} and V_{N} is close to −V_{D} and the other one is close to V_{S}+V_{D}. Thus one method to detect the zero-crossing moment of I_{P} is to compare either V_{P} or V_{N} (depending on the sign of V_{piezo}) with a reference voltage V_{ref}, for example using two (continuous-time) comparators. The reference voltage V_{ref} may be set slightly higher than the negative value of the voltage drop of the diodes (−V_{D}). If the voltage drop of the diodes is very small, V_{ref} may be directly connected to the ground. Alternatively, however, other techniques (such as a current sensing resistor) may be employed.

As described above, the power supply (denoted V_{DD}) for the system may be an external power supply such as a battery; it may also be obtained from a voltage regulator by regulating the voltage across the reservoir capacitor C_{S}. In this case, the system is self-powered.

In some preferred embodiments one or more voltage level shifters may be provided between the pulse sequence generator 656 and circuit 600, more particularly the switches of the circuit. This facilitates overdriving the switches, to improve the degree to which they are turned ON/OFF. For example there may be three voltage level shifters to shift the voltage levels of all the pulse signals (φ1, φ2 and φ3) to a higher ON level and a negative OFF level. If there are more than three pulses, more level shifters may be employed. The level shifters are employed to overdrive the switches to turn them fully ON or OFF. In order to generate the overdrive voltage levels (a higher voltage level and/or a negative voltage level), a DC-DC voltage boost converter and a DC-to-DC-voltage inverter may be employed. These voltage levels are generated from the power supply V_{DD}.

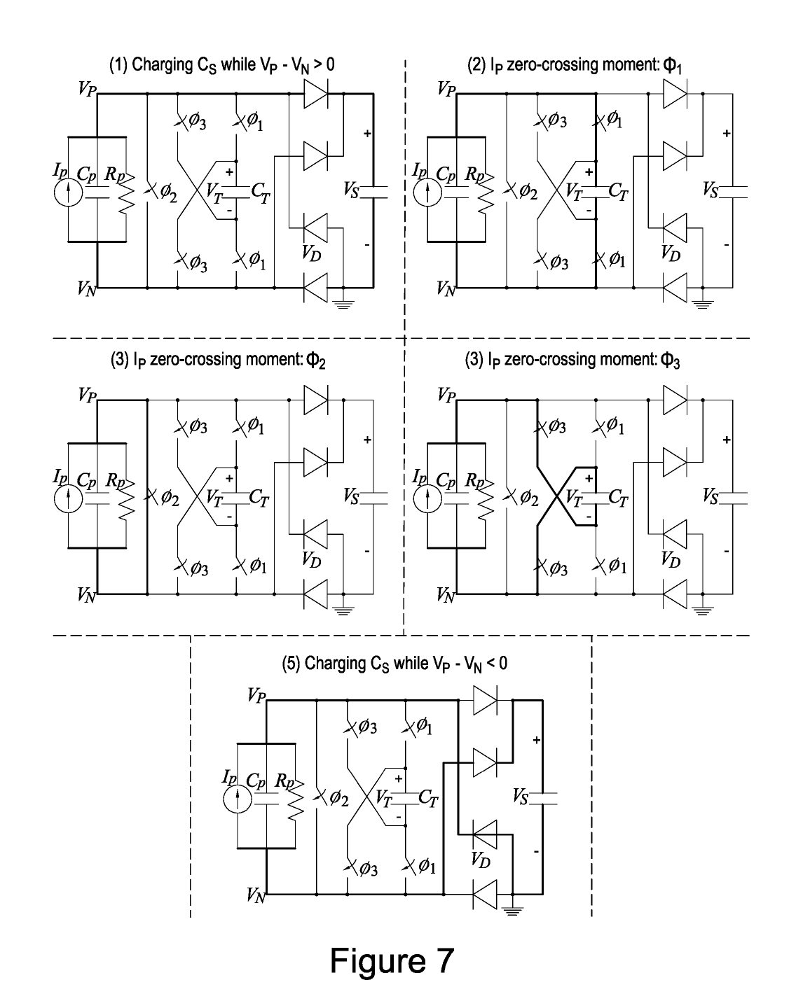

FIG. 7 illustrates in more detail the operation of circuit 600. Thus before I_{P} reaches its zero-crossing point the charge generated by the piezoelectric harvester flows into reservoir capacitor C_{S}, as shown in step (1). The polarization of the voltage across the piezoelectric harvester is assumed to be V_{piezo}>0, hence the top and bottom diodes are conductive and V_{piezo}=V_{S}+2V_{D} during this time. At the zero-crossing point of I_{P} pulse φ1 is generated to enable some charge from C_{P} flow onto C_{T} (step (2)). In the next phase (step (3)), φ2 turns ON the switch across the piezoelectric harvester and clears the remaining charge in C_{P}. In phase φ3, C_{T} is connected to the piezoelectric harvester in an opposite sense, and hence V_{piezo} goes to a negative value as the piezoelectric harvester acquires a negative charge (step(4)). After phase φ3, the polarization of I_{P} changes and the magnitude of V_{piezo} increases to −(V_{S}+2V_{D}), when the middle two diodes become conductive to start charging C_{S} again. In the voltage inversion process shown in FIG. 7 the order of the three signals is φ1, then φ2, then φ3 because V_{P}>V_{N} before the zero-crossing moment, and V_{piezo} is inverted from V_{S}+2V_{D} to a negative value. When V_{P}<V_{N} the order of the three signals is reversed to φ3, then φ2, then φ1. The waveforms of FIG. 4, described above, further illustrate this process.

Performance Analysis

It is useful to calculate how much charge is inverted, from which can be derived a condition to optimize performance.

Before a zero-crossing moment, it is assumed that V_{piezo} is positive and equal to V_{S}+2V_{D}, denoted V₀ for simplicity. C_{T} is assumed to have no charge initially and hence V_{T}=0 V. At the first zero-crossing moment of I_{P}, φ1 is turned ON because V_{piezo} is positive. C_{P} and C_{T} are connected and charge flows into C_{T} until the voltages across the two capacitors are equal. As the total charge remains unchanged the voltage across C_{P} and C_{T} at the end of the first phase is:

$${V}_{piezo 1} = {V}_{T 1} = \frac{{C}_{P}}{{C}_{P} + {C}_{T}} {V}_{0}$$

In the second phase pulse φ2 is generated and the remaining charge on C_{P} is cleared. Hence, the voltage across C_{P} and C_{T} at the end of the second phase is:

$${V}_{piezo 2} = 0$$

$${V}_{piezo 2} = {V}_{T 1 } = \frac{{C}_{P}}{{C}_{P} + {C}_{T}} {V}_{0}$$

In phase φ3, C_{T} is connected with C_{P} again, but in an opposite direction to charge C_{P} to a negative voltage. As the total charge in the two capacitors is the remaining charge on C_{T} the voltages V_{piezo} and V_{T} at the end of this phase are:

$${V}_{piezo 3} = - {V}_{T 3} = - \frac{{C}_{P} {C}_{T}}{{( {C}_{P} + {C}_{T} )}^{2}} {V}_{0}$$

It can be seen that V_{piezo} is negative at the end of the zero-crossing moment. By setting the derivative of the above expression to 0, it can be found that V_{piezo3} attains its minimum value when C_{T}=C_{P}. Therefore the minimum value of V_{piezo} at the end of the first charge inversion is:

$${V}_{piezo 3} = - {V}_{T 3} = - \frac{1}{4} {V}_{0} ( while {C}_{P} = {C}_{T} )$$

The resulting voltage above for V_{piezo3} is obtained after the first charge inversion and the initial voltage across C_{T} is assumed at 0 V at the beginning. However before the second zero-crossing moment, V_{T} is no longer 0 V, but ¼V₀. V_{piezo} now equals −V₀ and will be inverted from negative to positive. Assuming C_{T}=C_{P} is chosen for the calculations below, V_{piezo} and V_{T} values after each phase of φ1, φ2, and φ3 at the second charge inversion stage are:

$$before {φ}_{3} \text{:} {V}_{piezo} = - {V}_{0} , {V}_{T} = \frac{1}{4} {V}_{0} \\ ⇒ after {φ}_{3} \text{:} {V}_{piezo} = - {V}_{T} = - ( \frac{1}{4} + 1 ) \frac{1}{2} {V}_{0} \\ ⇒ after {φ}_{2} \text{:} {V}_{piezo} = 0 V , {V}_{T} = ( \frac{1}{4} + 1 ) \frac{1}{2} {V}_{0} \\ ⇒ after {φ}_{1} \text{:} {V}_{piezo} = {V}_{T} = ( \frac{1}{4} + 1 ) \frac{1}{4} {V}_{0} = ( {( \frac{1}{4} )}^{2} + \frac{1}{4} ) {V}_{0} = \frac{5}{16} {V}_{0}$$

As 5/16>¼ more charge is inverted during the second zero-crossing than the first. After n charge inversion stages the resulting magnitude |V_{piezo}| at the end of the nth inversion stage is:

$$\vert {V}_{piezo} \vert = ( {( \frac{1}{4} )}^{n} + … {\begin{matrix}1 \\ 4\end{matrix}}^{-} ⊢ \frac{1}{4} ) {V}_{0} = {\sum }_{1 \leq i \leq n} {( \frac{1}{4} )}^{i} {V}_{0} = \frac{\frac{1}{4} - {( \frac{1}{4} )}^{n}}{1 - \frac{1}{4}} {V}_{0} ⇒ {lim}_{n \to ∞} \vert {V}_{piezo} \vert = \frac{1}{3} {V}_{0}$$

As n tends to infinity, V_{piezo}|_{n→∞}=⅓V₀, which implies that theoretically one third of charge can be inverted if C_{T}=C_{P}.

One can also calculate the power that can be harvested and stored in the storage capacitor C_{S} at the output of the circuit. Assuming that the piezoelectric harvester is excited with a sinusoidal signal, the corresponding current source can be written as I_{P}=I₀ sin ωt, where ω=2πf₀ and f₀ is the excitation frequency. The total charge that can be generated by the harvester in a half cycle T/2 can be calculated as:

$${Q}_{T \text{/} 2} = {\int }_{0}^{\frac{T}{2}} {I}_{0} sin ω tdt = \frac{2 {I}_{0}}{ω} = \frac{{I}_{0}}{π {f}_{0}}$$

As shown above, a third of the charge can be inverted at each zero-crossing, which occurs each half cycle. After the zero-crossing the piezoelectric harvester still needs to charge its internal capacitor C_{P} to from ±(V_{S}+2V_{D}) to ±(V_{S}+2V_{D}) and this amount of charge is wasted. Therefore, the useful charge that flows into C_{S} in a half cycle is:

$${Q}_{S} = {Q}_{T \text{/} 2} - \frac{2}{3} ( {V}_{S} + 2 {V}_{D} ) {C}_{P} = \frac{{I}_{0}}{π {f}_{0}} - \frac{2}{3} ( {V}_{S} + 2 {V}_{D} ) {C}_{P}$$

The average harvested power can then be expressed as:

$$P = {V}_{S} \frac{{Q}_{S}}{T \text{/} 2} = 2 {f}_{0} {V}_{S} {Q}_{S} = 2 {f}_{0} {V}_{S} ( \frac{{I}_{0}}{π {f}_{0}} - \frac{2}{3} ( {V}_{S} + 2 {V}_{D} ) {C}_{P} )$$

With a given excitation level, where I₀ is a constant, the power attains a maximum value when

$${V}_{S} = \frac{3 {I}_{0}}{4 π {f}_{0} {C}_{P}} - {V}_{D} .$$

Assuming the voltage drop of the diodes is negligible such that V_{D}≈0 the maximum power can be expressed as:

$${P}_{max} = \frac{3 {I}_{0}^{2}}{4 {π}^{2} {f}_{0} {C}_{P}}$$

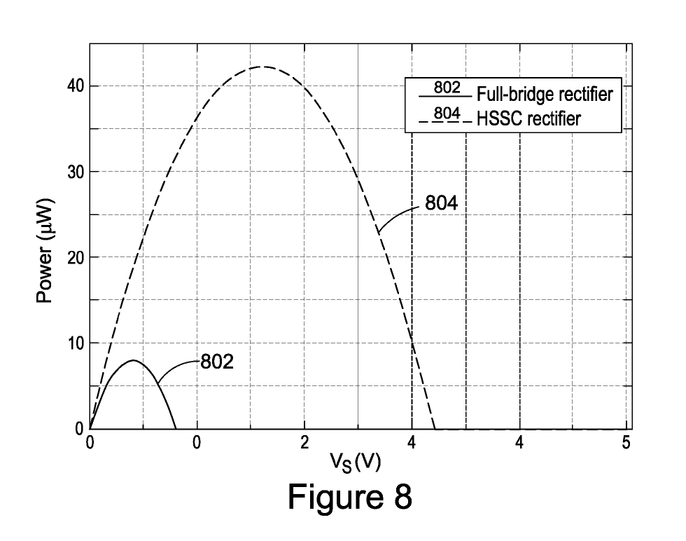

FIG. 8 shows the theoretical output electrical power from a piezoelectric harvester while using a simple full-bridge rectifier 802 and an HSSC rectifier of the type described above 804. The peak-to-peak open-circuit voltage from the piezoelectric harvester is set as 2.4 V and the voltage drop of diodes is 0.2 V; the voltage across the reservoir capacitor is varied from 0 V to 5 V. FIG. 8 shows that the HSSC rectifier design is able to extract 5.4 times more power from the energy harvester than the full-bridge rectifier.

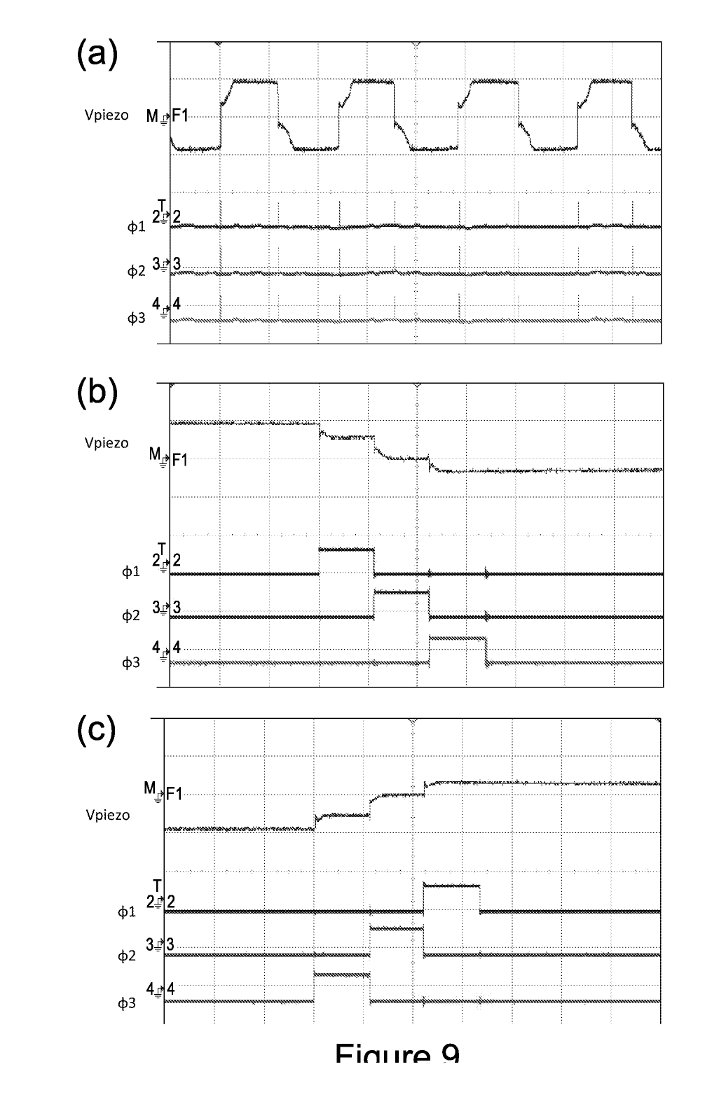

The design was experimentally evaluated using a commercially available piezoelectric harvester of dimension 47 mm×36 mm (Mide Technology Corporation V20 W). A shaker (LDS V406 M4-CE) was excited at the natural frequency of the piezoelectric harvester, 82 Hz, driven by a sine wave from a function generator (Agilent Technologies 33250A) amplified by a power amplifier (LDS PA100E Power Amplifier). The test circuit was powered by an external power supply at 1.8 V. FIGS. 9a to 9c show experimentally measured waveforms of V_{piezo} and the three switching signals which correspond to the simulated waveforms of FIGS. 4a to 4c; as can be seen there is a good match.

Compared to a full-bridge rectifier, embodiments of the interface circuit we describe can significantly improve the energy efficiency by inverting V_{piezo} for each half cycle of input excitation. Unlike a conventional SSHI power-conditioning interface circuit, embodiments of the invention do not employ an inductor to perform the charge inversion, which can significantly reduce the overall volume and cost of a vibration-based energy harvesting system. Also unlike the SSHI interface circuit, the pulse width of the pulses used in the switches for switched capacitors does not need to be precisely tuned: In preferred embodiments the pulse width is preferably merely longer than the time constant of the RC loop, to allow the majority of the charge to be shared between C_{P} and one of the temporary switched capacitors. Table 1 below shows a comparison between the performance of a full-bridge rectifier circuit, a SSHI interface circuit, and embodiments of the interface circuit we describe.

TABLE 1

| | Full-bridge | | Switched capacitor |
|---|---|---|---|
| | rectifier | SSHI | interface circuit |
| Stability | High | Low | Moderate |
| Power consumption | None | <1 μW | <1 μW |
| Efficiency | Low | From high to | From high to |
| | | very high* | very high** |
| System volume | Small | Large | Moderate |
| Cost | Low | High | Moderate |

*Depending upon how large an inductor is used.
**Depending upon how many switched capacitors are used.

### Example Implementation

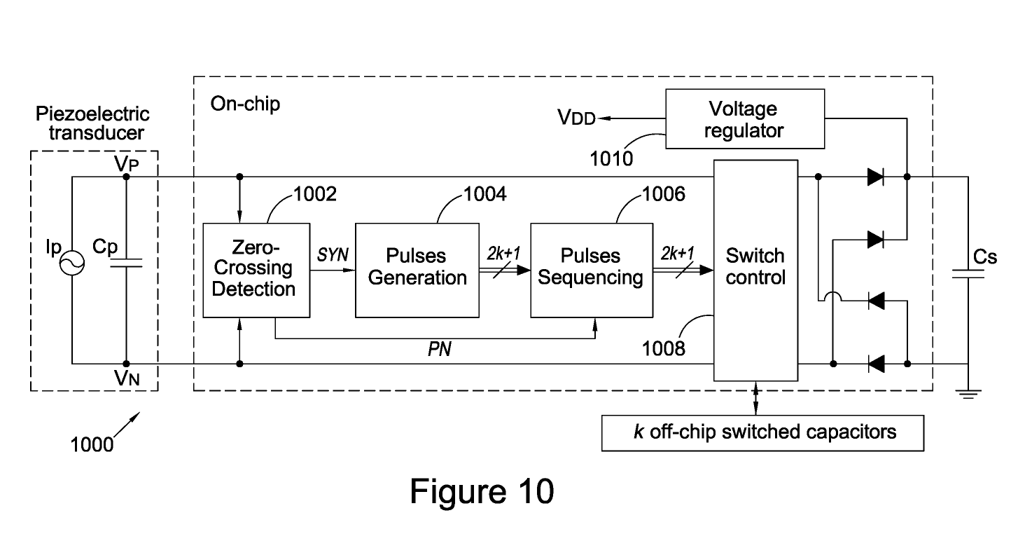

A further example implementation will now be described with reference to FIGS. 10 to 18. Thus FIG. 10 shows the system architecture of this further example implementation of the HSSC interface circuit 1000. The five blocks which, in embodiments, are implemented on-chip are the zero-crossing detection 1002, pulse generation 1004, pulse sequencing 1006, switch control 1008 and voltage regulator 1010 blocks. At each zero-crossing moment of I_{P}, a rising edge is generated in signal SYN and the signal PN indicates the direction that V_{PT} will be flipped, where V_{PT}=V_{P}−V_{N}. The signal PN is used here because the pulse phase orders for different voltage flip directions are different, as shown in FIG. 5b.

Assuming there are k switched capacitors employed in the HSSC circuit, after the pulse generation block 1004 reads a rising edge in SYN, 2k+1 sequential pulses are generated. In the following pulse sequencing block, these 2k+1 signals are sequenced according to the level of the signal PN. Then, these sequenced 2k+1 signals are used to drive analog switches in the switch control block 1008 to perform voltage flipping with the k off-chip capacitors. In order to achieve the optimal voltage flip efficiency, the values of the k off-chip capacitors are chosen as C₁=C₂= . . . Cₖ=C_{P}. In embodiments a voltage regulator, preferably with over-voltage protection, is employed to make the system self-powered. The internal transistor-level circuit diagrams and operations for each block are presented and explained below.

Zero-Crossing Detection

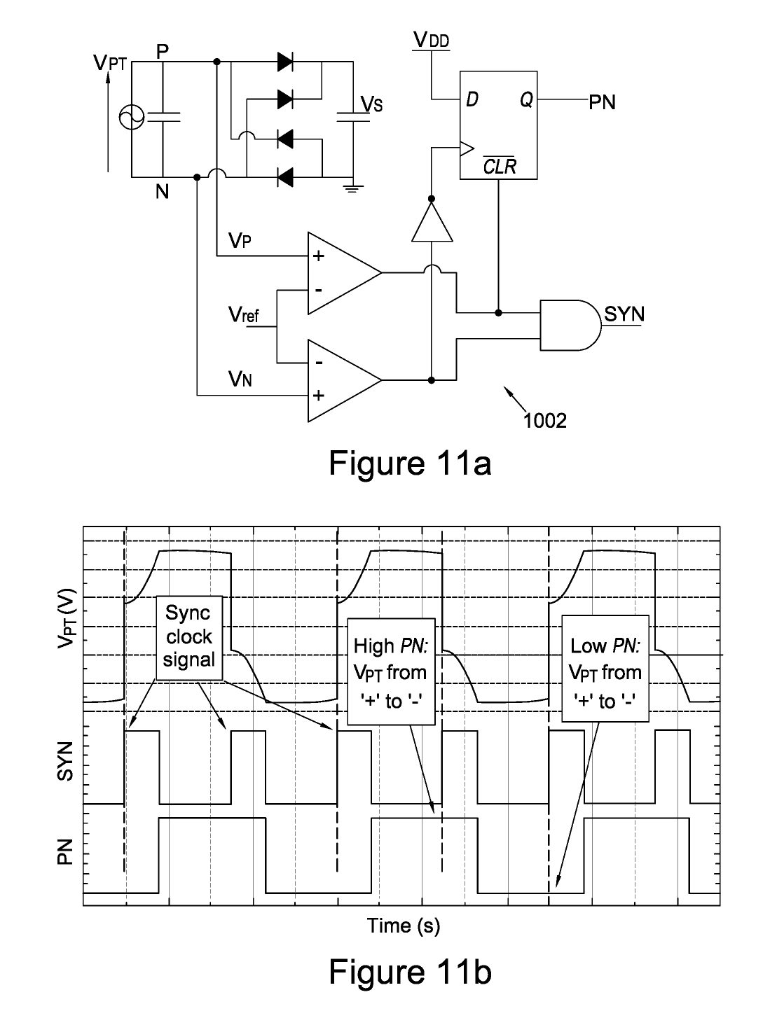

FIG. 11a shows an example circuit diagram of the zero-crossing detection block 1002. In order to find the zero-crossing moment of the current source I_{P}, two continuous-time comparators are employed to compare V_{P} and V_{N} with a reference voltage V_{ref}. While I_{P} is close to zero, the diodes of the full-bridge rectifier (FBR) are just about to turn OFF. At this moment one of V_{P} and V_{N} is close to −V_{D} and the other one is close to V_{S}+V_{D}. Hence, the reference voltage V_{ref} is set slightly higher than the negative value of the voltage drop of a diode (−V_{D}) so that either V_{P} or V_{N} going from −V_{D} towards positive can trigger the comparator and generate a synchronous signal. The outputs of these two comparators are ANDed so that a rising edge in the SYN signal is generated to flip the voltage V_{PT} for each zero-crossing moment of I_{P}. FIG. 11b shows waveforms illustrating the operation of this block. A signal labelled PN is also generated in this block, which indicates the polarization of V_{PT} before it is flipped at each zero-crossing moment. This signal is then used in the pulse sequencing block 1006 to help sequence the switch-driving pulses.

Pulse Generation

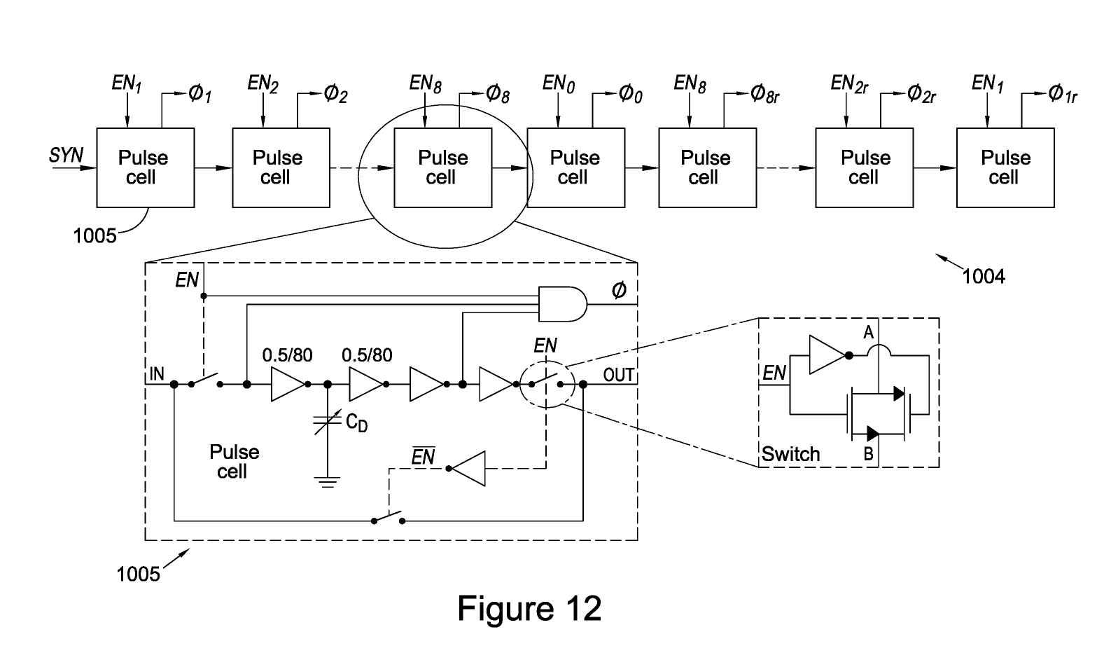

FIG. 12 shows an example circuit diagram of the pulse generation block 1004 for up to 8 switched capacitors in the HSSC interface circuit. In the example 17 pulse cells 1005 are employed in this block to generate up to 17 sequential pulses, of which the pulse width can be tuned externally. The input signal SYN is the synchronous clock signal generated from the zero-crossing detection block 1002. A rising edge in SYN drives the 17 pulse cells sequentially to generate one individual pulse in each cell. The 8 off-chip switched capacitors can be selectively enabled by input signals EN₁-EN₈ and signal EN₀ enables the phi₀ switch, which aims to clear the residual charge in C_{P}. These 9 digital input signals can be set externally according to the number of switched capacitors employed. If all of these 9 signals are low, the interface circuit simply works as a full-bridge rectifier. The input EN₀ is forced to high if any of EN₁-EN₈ are high because the residual charge in C_{P} needs to be cleared in the middle phase of the voltage flipping process. FIG. 12 also shows an example circuit diagram for a pulse cell 1005. The pulse signal is generated by ANDing the delayed and inverted versions of the input signal. For the very first pulse cell, the input signal is SYN and the input signals for the following cells are delayed versions of SYN. The delay in one pulse cell is performed by using two weak inverters charging a capacitor. The pulse width of the generated pulse for each cell can be tuned by adjusting the variable capacitor, which can be set externally. The three switches in one pulse cell are CMOS analog switches, which aims to enable and bypass the selected pulse cells. If any of EN₁-EN₈ signals are low, the corresponding pulse cells for the disabled capacitors are bypassed so that the SYN signal has almost no delay while bypassing these cells.

Pulse Sequencing

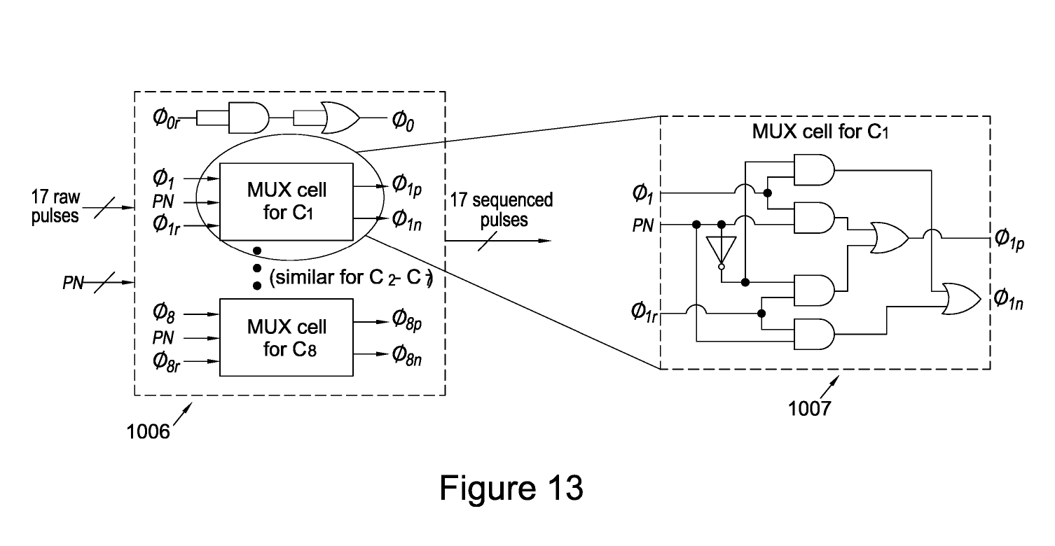

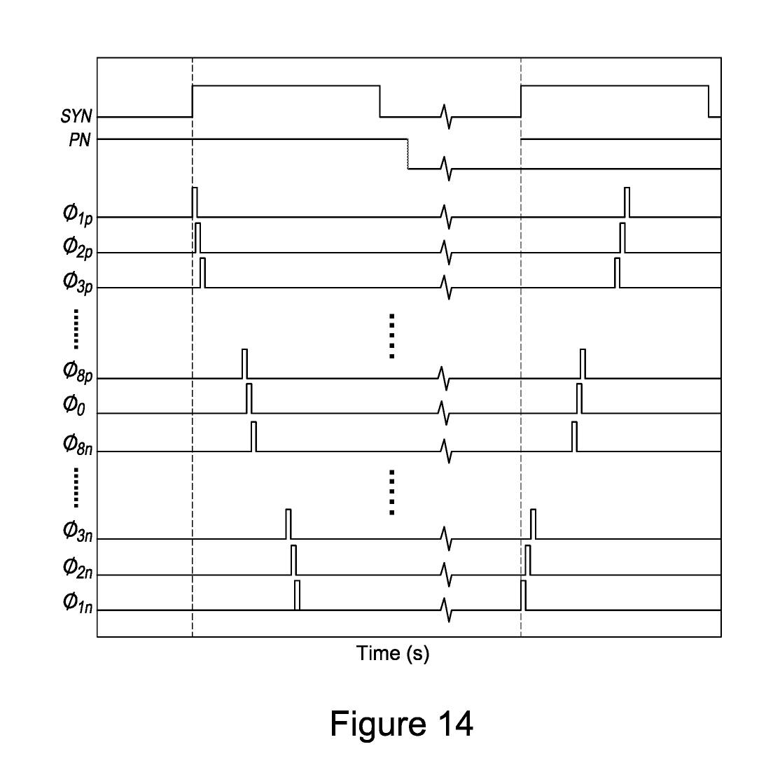

After the up to 17 sequential pulses are generated, they are sequenced before driving the switches to flip V_{PT}. FIG. 13 shows an example circuit diagram for the pulse sequencing block 1006, which in this example comprises 8 multiplexers 1007. While the input signal PN is high, V_{PT} should be flipped from positive to negative. In this case, the output sequence of the 17 pulses after the sequencing block should be ϕ₁ₚ→ϕ₂ₚ→ϕ₃ₚ→ϕ₄ₚ→ϕ₅ₚ→ϕ₆ₚ→ϕ₁ₚ→ϕ₈ₚ→ϕ₀→ϕ₈ₙ→ϕ₇ₙ→ϕ₆→ϕ₅ₙ→ϕ₄ₙ→ϕ₃ₙ→ϕ₂ₙ→ϕ₁ₙ. While PN is low, the pulse sequence is completely inversed. Generally the pulse ϕ₀ is in the middle of the sequence so it does not need sequencing. However, two redundant gates (AND and OR gates) are added for ϕ₀, which aims to ensure that all pulses have the same delay to avoid overlapping. FIG. 14 shows waveforms associated with pulse sequencing block 1006 for different PN levels.

Switch Control and Voltage Regulation Blocks

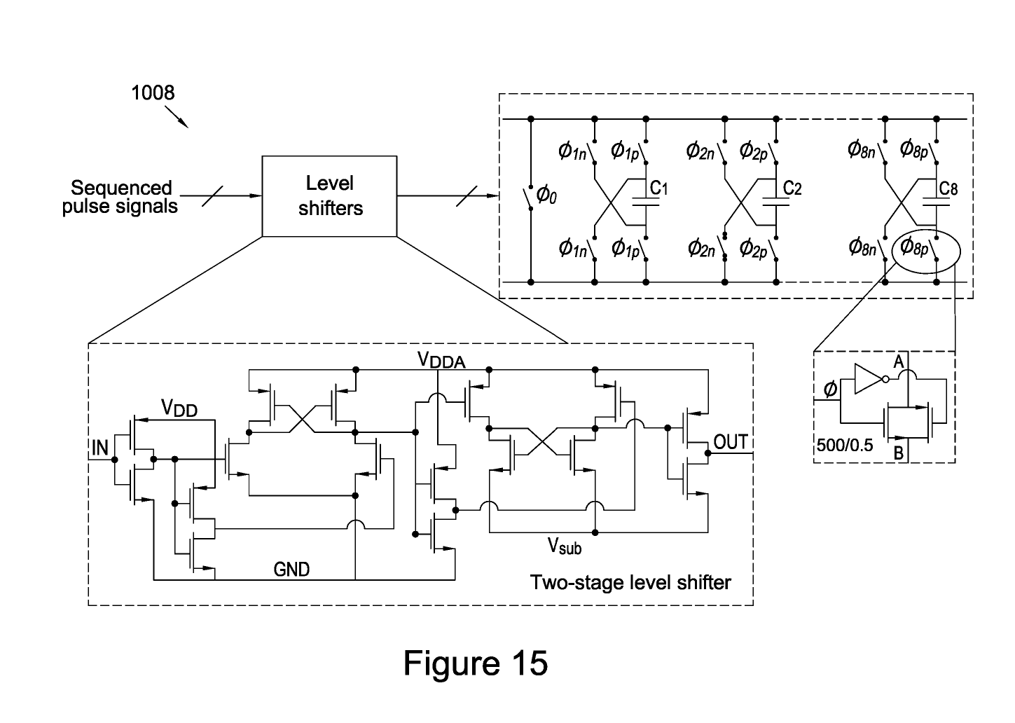

FIG. 15 shows an example circuit diagram of the switch control block 1008, which here comprises 17 two-stage level shifters and 33 analog CMOS switches. The 8 capacitors C₁-C₈ are in this example implemented off-chip as their capacitances are 45 nF, equal to the internal capacitance of the piezoelectric transducer C_{P}. The sequenced pulses obtained from the pulse sequencing block are not be directly used for driving the 33 switches because different voltage levels are employed. For each switch, the voltage on either side varies over a wide range between −V_{D} and V_{S}+V_{D}; however, the voltage levels of the pulses signals from the pulse sequencing block are 0V and 1.5V (V_{DD}=1.5V is used in this implementation). Therefore, the high and low levels of the switch driving signals are shifted to a larger voltage range in order to fully turn ON and OFF the 33 switches.

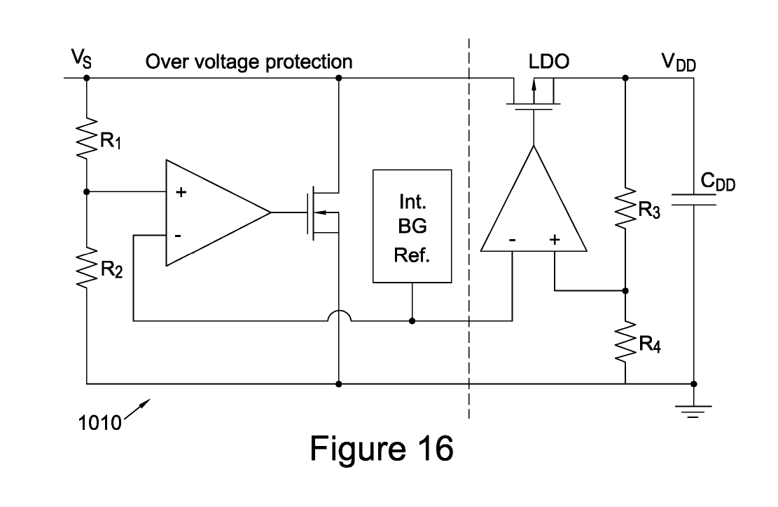

FIG. 16 shows an example implementation of an over-voltage protection (OVP) and a voltage regulator circuit 1010. The OVP aims to limit the voltage stored in the capacitor C_{S} and the voltage regulator is employed to provide a stable 1.5V supply to the interface circuit with the harvested energy. The resistors may be off-chip implemented with values R₁=100M, R₂=10M, R₃=50M, R₁=100M.

Measurement Results

The HSSC interface circuit 1000 was designed and fabricated in a 0.35 m HV CMOS process. The system was experimentally evaluated using a commercially available piezoelectric transducer (PT) of dimension 58 mm×16 mm (Mide Technology Corporation V21BL). This PT has an measured internal capacitance of C_{P}=45 nF and the 8 off-chip switched capacitors were chosen with the equal capacitances of 45 nF to achieve the optimal voltage flip efficiency. During the measurement, a shaker (LDS V406 M4-CE) was excited at the natural frequency of the PT at 92 Hz and driven by a sine wave from a function generator (Agilent Technologies 33250A 80 MHz waveform generator) amplified by a power amplifier (LDS PA100E Power Amplifier). A super capacitor was employed as the energy storage capacitor (AVX BestCap BZ05CA103ZSB) with a measured capacitance C_{S}≈5.2 mF. As the circuit is self-sustained with an on-chip voltage regulator, the voltage supply from the voltage regulator is only available when voltage across the storage capacitor satisfies V_{S}≥1.5V. While V_{S}<1.5V, the interface circuit simply works as a full-bridge rectifier (FBR) as all the 33 switches are OFF until V_{S} is charged to 1.5V. Hence, an external power supply at 1.5V was used while measuring the harvested power for V_{S}<1.5V.

Table 2, below, lists the power consumption due to different blocks of the HSSC interface circuit 1000.

TABLE 2
Breakdown of the chip power consumption

| | | |
|---|---|---|
| Loss mechanism | Power loss | Percentage |

| | | | |
|---|---|---|---|
| Zero-crossing detection | 189 | nW | 13.2% |
| Pulse generation | 93 | nW | 6.5% |
| Pulse sequencing | 0.3 | nW | 0.02% |
| Switch control | 690 | nW | 48.3% |
| Voltage regulator | 458 | nW | 32% |
| Total | 1.43 | μW | 100% |

The values shown in the table are obtained from simulations with assumptions that 8 switched capacitors are employed (with 80% voltage flip efficiency) and the PT resonant frequency is 92 Hz. Employing fewer switched capacitors can reduce the power loss due to the “pulse generation” and “switch control” blocks significantly. This is because fewer pulse signals are generated and fewer switches in the switch control block are driven in this case. The PT resonant frequency also affects the power consumption of these two blocks because a series of pulse signals is generated for every half period of the excitation frequency. Hence a higher frequency results in more pulse signals and more power consumed in generating pulses and driving switches.

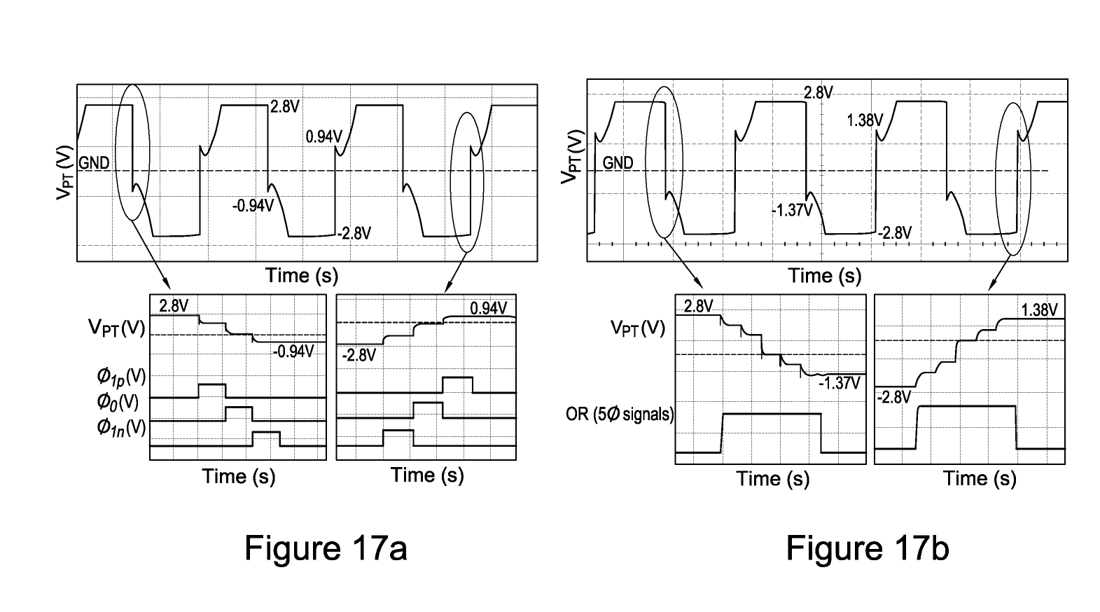

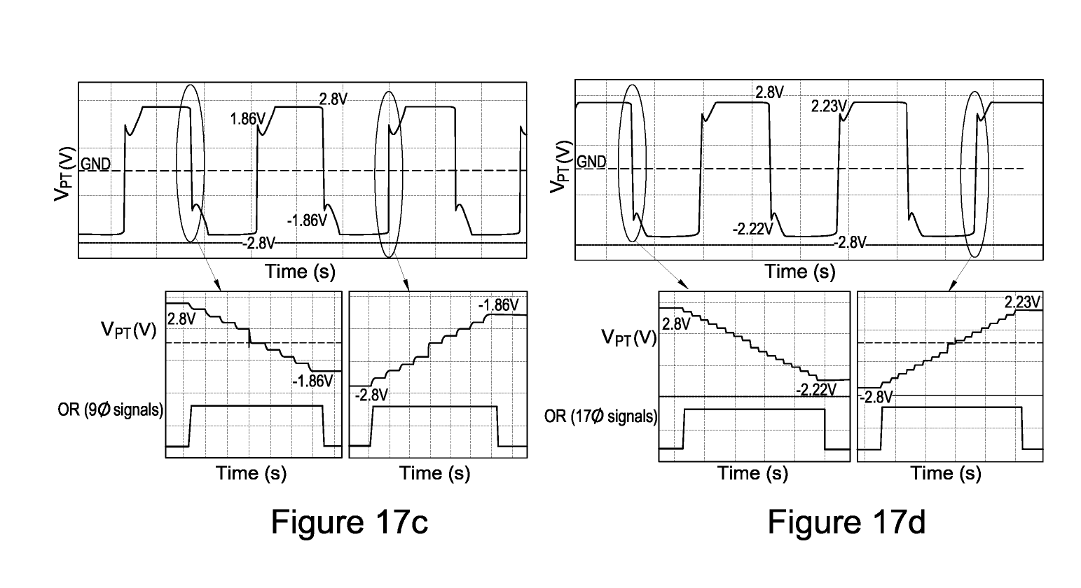

FIGS. 17a to 17d show measured waveforms from the HSSC interface circuit 1000 with the numbers of enabled switched capacitors are set to 1, 2, 4 and 8, respectively. From FIG. 17a it can be seen that the voltage across the piezoelectric transducer V_{PT} is flipped from ±2.8V to ∓0.94V. The voltage flip efficiency is around ⅓, which matches the calculated efficiency. Zoomed-in voltage flipping instants for V_{PT} flipping from positive to negative and from negative to positive are also shown in the figure together with the three switch signals ϕ₁ₚ, ϕ₀ and ϕ₁ₙ. There are only 3 switch signals used for 1 switched capacitor because the switch signal number required for k switched capacitors is 2k+1, as mentioned previously. In order to flip V_{PT} in two different directions, the sequence of the switched signals are inversed, as previously explained. When 2, 4 and 8 switched capacitors are enabled (FIGS. 17b to 17d), V_{PT} is flipped with efficiencies of ½, ⅔ and ⅘, respectively. These results also closely match calculations. As more switch signals are needed to drive more capacitors, these signals are ORed for display due to the limited number of oscilloscope channels. Although the sequence of the switched signals cannot be seen from the ORed version, their sequences for different voltage flip direction are completely reversed. As explained above, the middle signal ϕ₀ aims to clear the residual charge in C_{P} after most of charge has been transferred into the switched capacitors. From the zoomed-in voltage flip instants in the figures, it can be seen that V_{PT} goes to 0V at the very middle pulse and it is flipped to an opposite polarization during the following pulses.

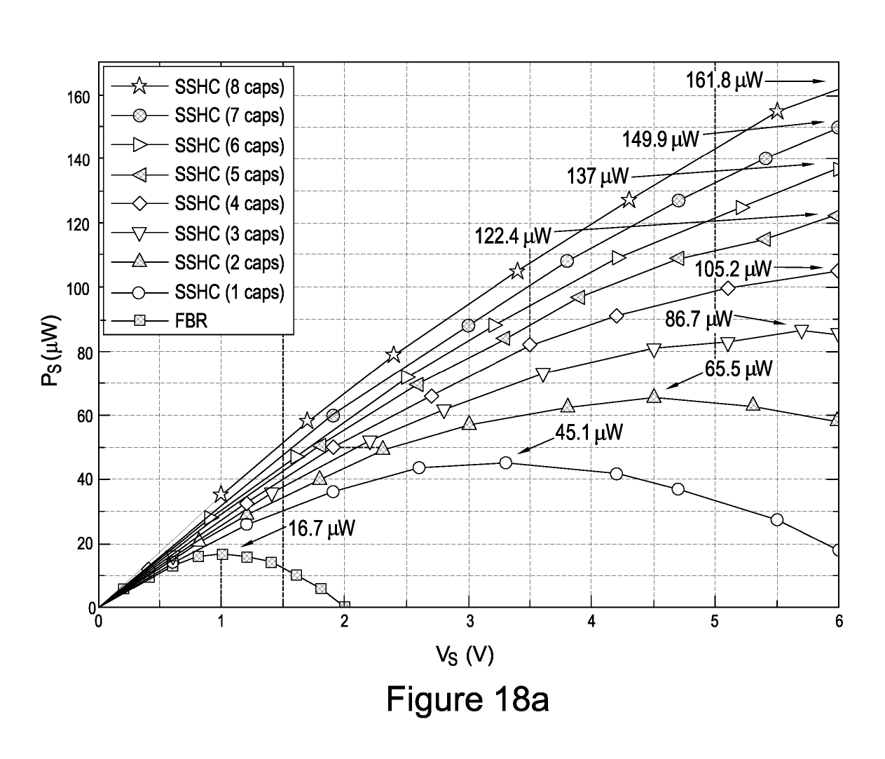

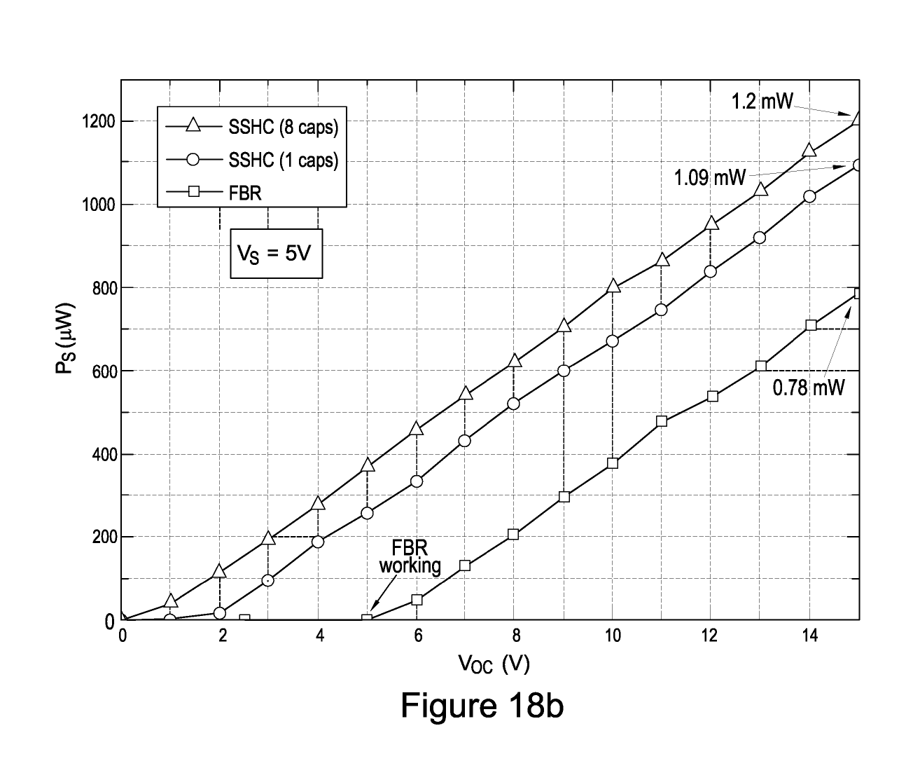

FIG. 18 shows the measured electrical output power of the PT with a conventional full-bridge rectifier (FBR) and with the proposed HSSC rectifier with up to 8 switched capacitors. The electrical output power is measured and calculated from a small voltage increase of V_{S} in a short period of time, where V_{S} is the voltage across the storage capacitor C_{S} connected to the output of a FBR (refer to FIG. 3). The power at a specific V_{S} is calculated as

$$P = \frac{1}{2 T} {C}_{S} ( {( {V}_{S} + Δ {V}_{S} )}^{2} - {V}_{S}^{2} ) ,$$

where ΔV_{S} is a small voltage increase in V_{S} and T is the time elapsed. In FIG. 18a the voltage across the capacitor C_{S} is varied to measure the peak power points for each configurations of the interface circuits. During these measurements, the PT is excited at an acceleration level of 1.2 g, which produces an open-circuit voltage amplitude of V_{OC}=2.5V across the PT. From the figure, it can be seen that the output power of an FBR is around 16.7 W while an HSSC circuit with only 1 switched capacitor can output 45.1 W power, a 2.7×relative performance improvement with respect to the FBR. When two switched capacitors are employed the output power increases to 65.5 W with a 3.9× overall improvement. When the number of the switched capacitors is 8 the output power is increased to 161.8 W. Hence the output power with 8 switched capacitors improves the performance by 9.7× compared to an FBR. The trend of the power curve in the figure also implies that the output power for 8 switched capacitors can go higher for higher V_{S} values (providing the CMOS circuit is designed to work with sufficiently high voltages). FIG. 18b shows the output power with a fixed voltage V_{S}=5V when the excitation level is varied from 0 g to 7.5 g (equivalent to V_{OC} varying from 0V to 15V): An HSSC interface circuit with 8 switched capacitors can provide an output power up to 1.2 mW. Even with 8 switched capacitors the space occupied by these off-chip capacitors is still small compared to the inductor(s) required in other approaches.

We have thus described an inductor-less interface circuit for piezoelectric vibration-based energy harvesters employing switched capacitors to synchronously flip the residual charge across the piezoelectric transducer (PT) which significantly improve key circuit metrics. Compared to other interface circuits, such as SSHI (synchronized switch harvesting on inductor), SECE (synchronous electrical charge extraction) embodiments of the interface circuit we describe completely removes the requirement for an inductor to flip the voltage across the PT.

From theoretical calculations, the voltage flip efficiency is ⅓ when only one switched capacitor is employed and this efficiency approaches 80% with 8 switched capacitors. In order to achieve these optimal theoretical voltage flip efficiencies, the capacitances of the switched capacitors should preferably be substantially equal to the internal capacitance of the PT. For an SSHI interface circuit to achieve an equal voltage flip efficiency, a large inductor would be required, which is very impractical in miniaturized systems for real-world implementations. The measured results show that our HSSC interface circuit improves the performance by 9.7× compared to a full-bridge rectifier. The performance boost is higher than reported inductor-based interface circuits with smaller system volume requirements due to the proposed capacitor-based design and hence a much higher energy efficiency per unit volume can be obtained.

In principle full on-chip integration of the circuit and switched capacitors could be employed, for example for piezoelectric MEMS energy harvesters. This in turn could provide a new-class of fully integrated self-powered CMOS-MEMS sensor nodes.

No doubt many other effective alternatives will occur to the skilled person. It will be understood that the invention is not limited to the described embodiments and encompasses modifications apparent to those skilled in the art lying within the spirit and scope of the claims appended hereto.

1. A method of energy harvesting from an electromechanical device which provides energy in the form of charge separation, the method comprising:
providing alternating current (AC) electrical power from said electromechanical device to an energy storage device via a rectifier to convert positive and negative components of said AC power to power having a single polarity for storage on said storage device:
the method further comprising:
identifying when a current flow from said electromechanical device is substantially zero and, responsive to said identifying:
connecting and disconnecting a first charge storage capacitor in parallel with said electromechanical device with a first sense, such that charge on said electromechanical device is shared with said first charge storage capacitor, to collect charge from said electromechanical device on said first charge storage capacitor; and then
connecting and disconnecting said first charge storage capacitor in parallel with said electromechanical device in a second, opposite sense to said first sense, such that said collected charge on said first charge storage capacitor is shared with opposite polarity with said electromechanical device, to replace opposite polarity charge from said first charge storage capacitor onto said electromechanical device.

2. A method as claimed in claim 1 further comprising:
shorting said electromechanical device reduce or zero a charge on said electromechanical device between collecting said charge and replacing said opposite polarity charge.

3. A method as claimed in claim 2 wherein said connecting and said shorting comprises operating a plurality of controllable switches connected between plates of said first charge storage capacitor and power supply connections from said electromechanical device.

4. A method as claimed in claim 3 wherein said operating of said plurality of controllable switches comprises generating a sequence of pulses in synchronism with zero crossings of said AC current to control said switches in sequence to perform said connecting in said first sense, and said connecting in said opposite sense and, said shorting.

5. A method as claimed in claim 1 further comprising:
after connecting and disconnecting said first charge storage capacitor in said first sense, connecting and disconnecting a second charge storage capacitor in parallel with said electromechanical device, such that charge on said electromechanical device is shared with said second charge storage capacitor, to collect residual charge from said electromechanical device on said second charge storage capacitor; and
prior to connecting and disconnecting said first charge storage capacitor on said opposite sense,
connecting and disconnecting said second charge storage capacitor in parallel with said electromagnetic device, such that collected charge on said second charge storage capacitor is shared with opposite polarity with said electromechanical device to replace opposite polarity charge from said second charge storage capacitor onto said electromechanical device.

6. A method as claimed in claim 1 comprising:
sequentially connecting and disconnecting a succession of charge storage capacitors across said electromechanical device in said first sense and in a first order, to successively share charge from said electromechanical device to collect charge from said electromechanical device; and then
sequentially connecting and disconnecting said succession of charge storage capacitors across said electromechanical device in said opposite sense and in a second, reverse order to replace stored charge onto said electromechanical device.

7. A method as claimed in claim 1 herein said electromechanical device comprises a piezoelectric material.

8. A circuit for energy harvesting from an electromechanical device which provides energy in the form of charge separation, the circuit comprising:
an input to receive alternating current (AC) electrical power from said electromechanical device;
a rectifier to convert positive and negative components of said AC power to power having a single polarity for storage on an energy storage device;
a zero-crossing circuit to identify when a current flow from said electromechanical device is substantially zero;
a first charge storage capacitor;
a first plurality of switches configured to connect and disconnect said first charge storage capacitor in parallel with said electromechanical device in a first sense and in a second opposite sense;
at least one shorting switch to short said electromechanical device to reduce or zero a charge on said electromechanical device; and
a controller, coupled to said zero-crossing circuit to control said first plurality of switches and said at least one shortening switch to:
connect and disconnect said first charge storage capacitor in parallel with said electromechanical device in said first sense to collect charge from said electromechanical device; then
short said electromechanical device reduce or zero a charge on said electromechanical device; and then
connect and disconnect said first charge storage capacitor in parallel with said electromechanical device in said opposite sense to return said collected charge to said electromechanical device with an opposite polarity.

9. A circuit as claimed in claim 8 comprising a plurality of said charge storage capacitors each with a respective plurality of switches to connect and disconnect a respective charge storage capacitor in parallel with said electromechanical device in said first sense and in said opposite sense.

10. A circuit as claimed in claim 9 wherein said controller is configured to control said switches to
sequentially connect and disconnecting a succession of said charge storage capacitors across said electromechanical device in said first sense and in a first order, to successively share charge from said electromechanical device to collect charge from said electromechanical device; and then to
sequentially connect and disconnect said succession of said charge storage capacitors across said electromechanical device in said opposite sense and in a second, reverse order to replace stored charge onto said electromechanical device.

11. A circuit as claimed in claim 8 wherein said electromechanical device comprises a piezoelectric material.

12. An energy harvesting circuit to harvest energy from a piezoelectric device, the circuit comprising:
an input comprising first and second connections to receive ac power from said piezoelectric device; and
a rectification stage, coupled to said input;
the circuit further comprising:
a first controllable multi-state switching system; and
a first charge storage capacitor coupled to said input connections by said first controllable multi-state switching system;
wherein said controllable multi-state switching system comprises two or more controllable switches configured such that when said switching system is in a storage state first and second plates of said first charge storage capacitor are respectively coupled to said first and second input connections; such that when said switching system is in a recovery state first and second plates of said first charge storage capacitor are respectively coupled to said second and first input connections; and such that when said switching system is in a quiescent state at least one of said plates of said first charge storage capacitor is decoupled from said input connections; and
a clock generator, synchronised to said ac power from said piezoelectric device, to control said switching system to switch from said quiescent state and transition between said storage and recovery states at a zero crossing of an ac current from said piezoelectric device.

13. An energy harvesting circuit as claimed in claim 12 wherein the circuit has a transitional state in which said input connections are connected together and comprises a switch to connect said input connections in said transitional state; and wherein said clock generator is configured to control said circuit into said transitional state in transitioning between said storage and recovery states.

14. An energy harvesting circuit as claimed in claim 12 comprising a second controllable multi-state switching system, and a second charge storage capacitor coupled to said input connections by said second controllable multi-state switching system; and wherein said clock generator is configured to control said first and second switching systems to successively switch said first switching system and then said second switching system between said quiescent state and a respective storage state and then back to said quiescent state, and then to successively switch said second switching system and then said first switching system between said quiescent state and a respective recovery state and then back to said quiescent state.

15. An energy harvesting circuit as claimed in claim 14 wherein the circuit has a transitional state in which said input connections are connected together and comprises a switch to connect said input connections in said transitional state; and wherein said clock generator is configured to control said circuit into said transitional state in transitioning between said storage and recovery states; and wherein said clock generator is configured to control said circuit into said transitional state between the storage and recovery switching sequences.
